(19) United States
(12) Patent Application Publication
(10) Pub. No.: US 2024/0402547 A1
(43) Pub. Date: Dec. 5, 2024

(54) DISPLAY DEVICE

(71) Applicant: Sharp Display Technology Corporation, Kameyama City (JP)

(72) Inventor: Masahiro IMAI, Kameyama City (JP)

(21) Appl. No.: 18/622,050

(22) Filed: Mar. 29, 2024

(30) Foreign Application Priority Data
May 30, 2023 (JP) 2023-088754

(51) Int. Cl. G02F 1/1345; G02F 1/1362; H01L 27/12

(52) U.S. Cl. CPC G02F 1/13452; G02F 1/136286; H01L 27/124

(57) ABSTRACT

A display device includes a display panel having a main surface including a display region and a non-display region, a driver, a first terminal provided at a position overlapping with the driver, a first wiring line connected to the first terminal, a second terminal provided at a position overlapping with the driver and being farther from the display region than the first terminal, and a second wiring line connected to the second terminal. The driver has a rectangular planar shape, and has a first side portion closest to the display region and a second side portion connected to the first side portion. The first wiring line extends from the first terminal and is disposed across the first side portion, and the second wiring line extends from the second terminal and is disposed across the second side portion.

### CROSS-REFERENCE TO RELATED APPLICATIONS

This application claims the benefit of priority to Japanese Patent Application Number 2023-088754 filed on May 30, 2023. The entire contents of the above-identified application are hereby incorporated by reference.

### BACKGROUND

### Technical Field

The technique disclosed in the present specification relates to a display device.

A display device described in U.S. Pat. No. 8,299,631 is known as an example of a display device including a driver in the related art. U.S. Pat. No. 8,299,631 discloses a semiconductor element as the driver. The semiconductor element included in the display device described in U.S. Pat. No. 8,299,631 is mounted on a display panel including a display portion. The semiconductor element includes a main surface having a rectangular shape with two long sides and two short sides, and a plurality of output terminals provided on the main surface, arranged in a direction along the long sides, and electrically connected to the display portion of the display panel. The plurality of output terminals include a plurality of first terminals disposed on a central portion side of the long sides, and a plurality of second terminals disposed on an end portion side of the long sides. At least the first terminals of the plurality of output terminals are disposed on one of the two long sides, and at least some of the second terminals are disposed on the other of the two long sides as compared with the first terminals.

### SUMMARY

In the semiconductor element included in the display device described in U.S. Pat. No. 8,299,631, the plurality of first terminals are arranged parallel to the long sides, whereas the plurality of second terminals are arranged so as to gradually approach, from the central portion side toward the end portion side of the one of the long sides, the other of the long sides. When the first terminals and the second terminals are arranged in this manner, neither the first terminals nor the second terminals are disposed in the vicinity of either end portion of the one of the long sides of the semiconductor element. Due to this, when the semiconductor element is thermocompression-bonded to the display panel via an anisotropic conductive film (ACF), deformation such as warpage is likely to occur in the vicinity of both end portions of the one of the long sides of the semiconductor element. For suppressing such deformation, it is conceivable to dispose bumps protruding from the semiconductor element toward the display panel in the vicinity of both end portions of the one of the long sides, similarly to the first terminals and the second terminals. However, when such bumps are disposed, it is necessary to take care that wiring lines do not interfere with the bumps in routing the wiring lines connected to the second terminals. This tends to increase the routing space for the wiring lines, and as a result, there is a problem that a frame width of the display panel is increased.

The technique described herein has been made based on the circumstances described above, and is directed to making the frame smaller.

(1) A display device related to the technique described in the present specification includes: a display panel having a main surface including a display region in which an image is displayed and a non-display region surrounding the display region; a driver attached to the non-display region of the display panel; a first terminal provided at a position overlapping with the driver in the non-display region of the display panel; a first wiring line provided in the non-display region of the display panel and connected to the first terminal; a second terminal provided at a position in the non-display region of the display panel, the position overlapping with the driver and being farther from the display region than the first terminal; and a second wiring line provided in the non-display region of the display panel and connected to the second terminal, in which the driver has a rectangular planar shape, has a side portion closest to the display region and in an outer peripheral portion as a first side portion, and has one side portion of two side portions connected to the first side portion as a second side portion, the first wiring line extends from the first terminal and is disposed across the first side portion, and the second wiring line extends from the second terminal and is disposed across the second side portion.

(2) In addition to (1) above, the display device may further include a third terminal provided at a position in the non-display region of the display panel, the position overlapping with the driver and being farther from the display region than the second terminal, the third terminal may be disposed at a position in which a distance between the third terminal and the second terminal is larger than a distance between the first terminal and the second terminal, and the second wiring line may extend from the second terminal toward the third terminal and cross the second side portion.

(3) In addition to (2) above, in the display device, a plurality of the second terminals may be arranged at intervals in a first direction being a direction parallel to the first side portion, a plurality of the second wiring lines may be provided to be connected to the plurality of the second terminals, respectively, and the plurality of the second wiring lines have extension lengths extending from the second terminals toward the third terminal, the extension lengths becoming shorter as the second terminals to be connected come closer to the second side portion.

(4) In addition to (2) or (3) above, the display device may further include: a fourth terminal provided at a position in the non-display region of the display panel, the position overlapping with the driver and being farther from the second side portion than the second terminal; and a third wiring line provided in the non-display region of the display panel and connected to the fourth terminal, in which a distance to the fourth terminal from the display region may be equal to a distance from the display region to the second terminal, and the third wiring line may extend from the fourth terminal and be disposed across the first side portion.

(5) In addition to (4) above, in the display device, a plurality of the first terminals, a plurality of the second terminals, and a plurality of the fourth terminals may be arranged at intervals in a first direction being a direction parallel to the first side portion, a plurality of the first wiring lines, a plurality of the second wiring lines, and a plurality of the third wiring lines may be provided to be connected to the plurality of the first terminals, the plurality of the second terminals, and the plurality of the fourth terminals, respectively, the plurality of the second terminals and the plurality of the fourth terminals may be disposed at positions displaced in the first direction with respect to the plurality of the first terminals, and each of the plurality of the third wiring lines may pass between two of the plurality of the first terminals adjacent to each other in the first direction.

(6) In addition to (4) or (5) above, in the display device, the driver may be capable of interchanging a signal output to the second terminal and a signal output to the fourth terminal.

(7) In addition to any one of (2) to (6) above, in the display device, the second terminal may have a rectangular planar shape, and may have a side portion farthest from the display region and in an outer peripheral portion as a third side portion, and the second wiring line may be connected to the third side portion of the second terminal.

(8) In addition to any one of (2) to (7) above, the display device may further include: a fifth terminal provided at a position in the non-display region of the display panel, the position overlapping with the driver and being closer to the second side portion than the second terminal; and a fourth wiring line provided in the non-display region of the display panel and connected to the fifth terminal, in which a distance to the fifth terminal from the display region may be equal to a distance from the display region to the second terminal, and the fifth terminal may have a rectangular planar shape, and may have a side portion closest to the second side portion and in an outer peripheral portion as a fourth side portion, and the fourth wiring line may be connected to the fourth side portion of the fifth terminal and may be disposed across the second side portion.

(9) In addition to any one of (1) to (8), the display device may further include: a plurality of pixel electrodes provided in the display region of the display panel; a plurality of switching elements provided in the display region of the display panel and connected to the plurality of pixel electrodes; and a plurality of image wiring lines provided in the display region of the display panel and connected to the plurality of switching elements, in which the plurality of image wiring lines may include first image wiring lines arranged at intervals in a first direction being a direction parallel to the first side portion, and connected to the first wiring lines, and second image wiring lines connected to the second wiring lines and located closer to an end of the display region than the first image wiring lines in the first direction.

(10) In addition to (9) above, the display device may further include: a third terminal provided at a position in the non-display region of the display panel, the position overlapping with the driver and being farther from the display region than the second terminal; a fifth wiring line provided in the non-display region of the display panel and connected to the third terminal; a scanning wiring line provided in the display region of the display panel and connected to the switching element; and a scanning circuit portion provided in the non-display region of the display panel and connected to the scanning wiring line, in which the fifth wiring line may extend from the third terminal, may be disposed across the second side portion, and may be connected to the scanning circuit portion.

(11) In addition to (9) above, the display device may further include: a flexible substrate attached to the non-display region of the display panel at a position where the driver is sandwiched between the flexible substrate and the display region; a third terminal provided at a position in the non-display region of the display panel, the position overlapping with the driver and being farther from the display region than the second terminal; a fifth wiring line provided in the non-display region of the display panel and connected to the third terminal; a scanning wiring line provided in the display region of the display panel and connected to the switching element; a scanning circuit portion provided at a position in the non-display region of the display panel and connected to the scanning wiring line, the position being aligned with the display region in the first direction; a sixth terminal provided at a position in the non-display region of the display panel and connected to the fifth wiring line, the position overlapping with the flexible substrate; a seventh terminal provided at a position on the flexible substrate and connected to the sixth terminal, the position overlapping with the display panel; an eighth terminal provided at a position on the flexible substrate, the position overlapping the display panel and being closer to an end in the first direction than the seventh terminal; a sixth wiring line provided on the flexible substrate and connected to the seventh terminal and the eighth terminal; a ninth terminal provided at a position in the non-display region of the display panel and connected to the eighth terminal, the position overlapping with the flexible substrate and being closer to an end in the first direction than the sixth terminal; and a seventh wiring line provided in the non-display region of the display panel and connected to the ninth terminal and the scanning circuit portion.

(12) In addition to any one of (1) to (8) above, the display device may further include: a plurality of pixel electrodes provided in the display region of the display panel; a plurality of switching elements provided in the display region of the display panel and connected to the plurality of pixel electrodes; a plurality of image wiring lines provided in the display region of the display panel and connected to the plurality of switching elements; a plurality of scanning wiring lines provided in the display region of the display panel and connected to the plurality of switching elements; a fourth terminal provided at a position in the non-display region of the display panel, the position overlapping with the driver and being farther from the second side portion than the second terminal; a third wiring line provided in the non-display region of the display panel and connected to the fourth terminal; a tenth terminal provided at a position in the non-display region of the display panel, the position overlapping with the driver and being farther from the second side portion than the first terminal; and an eighth wiring line provided in the non-display region of the display panel and connected to the tenth terminal, in which a distance to the fourth terminal from the display region may be equal to a distance from the display region to the second terminal, the third wiring line may extend from the fourth terminal and may be disposed across the first side portion, a distance to the tenth terminal from the display region may be equal to a distance from the display region to the first terminal, the eighth wiring line may extend from the tenth terminal and may be disposed across the first side portion, the third wiring line and the eighth wiring line may be connected to the plurality of image wiring lines, respectively, and the first wiring line and the second wiring line may be connected to the plurality of scanning wiring lines, respectively.

According to the technique described herein, it is possible to make a frame smaller.

### BRIEF DESCRIPTION OF DRAWINGS

The disclosure will be described with reference to the accompanying drawings, wherein like numbers reference like elements.

FIG. 1 is a plan view of a liquid crystal panel, a driver, and a flexible substrate according to a first embodiment.

FIG. 2 is a cross-sectional view of the liquid crystal panel, the driver, and the flexible substrate according to the first embodiment.

FIG. 3 is a plan view illustrating a pixel arrangement of the liquid crystal panel according to the first embodiment.

FIG. 4 is a plan view illustrating a display region and a placement region of a driver in an array substrate included in the liquid crystal panel according to the first embodiment.

FIG. 5 is a bottom view of the driver according to the first embodiment.

FIG. 6 is a cross-sectional view illustrating a connection state between an output terminal of the array substrate and an output bump of the driver according to the first embodiment.

FIG. 7 is a plan view illustrating a configuration of the placement region of the driver in the array substrate according to the first embodiment.

FIG. 8 is a graph showing a relationship between a position of a second terminal in an X-axis direction and a wiring line length of a second wiring line according to the first embodiment.

FIG. 9 is a plan view illustrating a liquid crystal panel, a driver, and a flexible substrate according to a second embodiment.

FIG. 10 is a plan view illustrating a placement region of the driver in an array substrate according to the second embodiment.

FIG. 11 is a plan view illustrating a display region and the placement region of the driver in the array substrate according to the second embodiment.

FIG. 12 is a plan view illustrating a configuration of a placement region of a driver in an array substrate according to a third embodiment.

FIG. 13 is a plan view illustrating a display region and the placement region of the driver in the array substrate according to the third embodiment.

FIG. 14 is a cross-sectional view illustrating a connection state between a sixth terminal and a ninth terminal of the array substrate and a seventh terminal and an eighth terminal of a flexible substrate according to the third embodiment.

FIG. 15 is a plan view illustrating a display region and a placement region of a driver in an array substrate according to a fourth embodiment.

FIG. 16 is a plan view illustrating a configuration of a placement region of a driver in an array substrate according to another embodiment (12).

### DESCRIPTION OF EMBODIMENTS

### First Embodiment

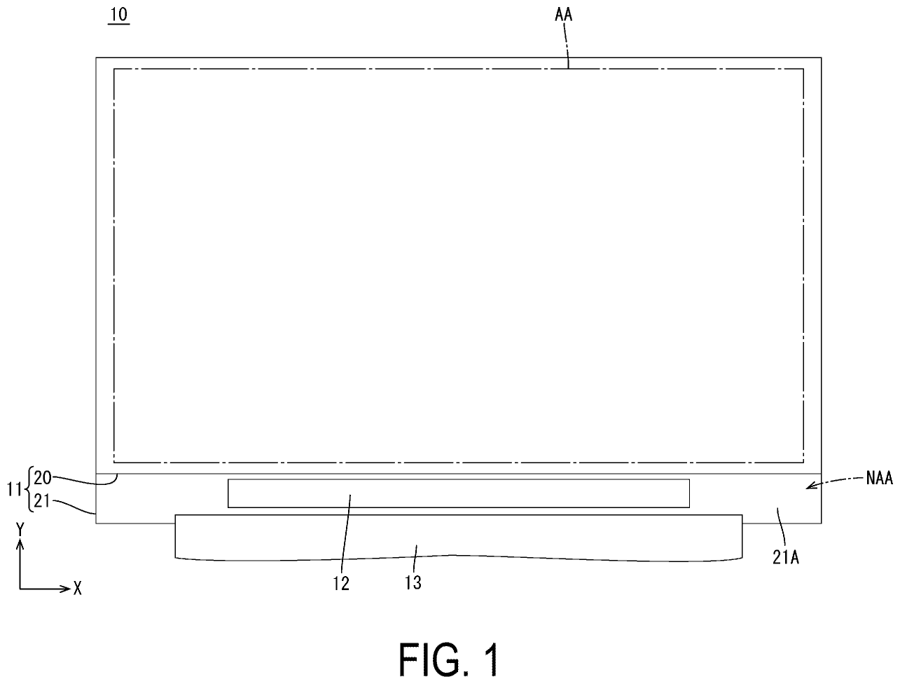

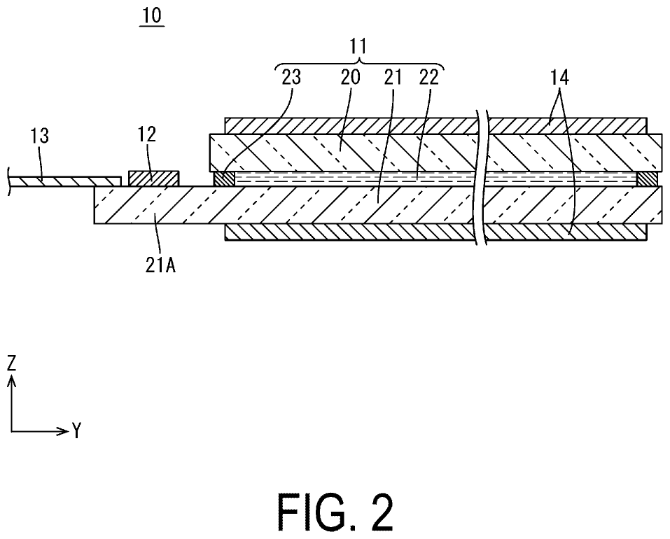

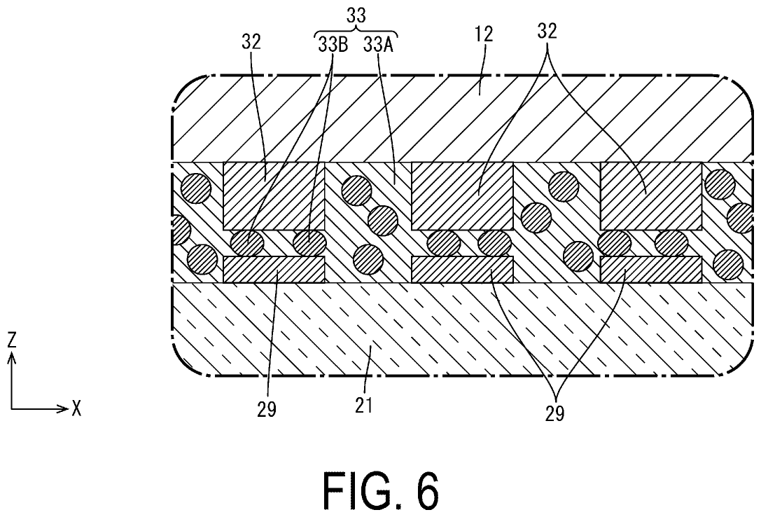

A first embodiment will be described with reference to FIGS. 1 to 8. In the present embodiment, a liquid crystal display device (a display device) 10 is described. Note that some drawings show an X-axis, a Y-axis, and a Z-axis, and directions of these axes are drawn so as to be common in all the drawings. An upper side and a lower side in FIG. 2 and FIG. 6 are defined as a front side and a rear side, respectively.

The liquid crystal display device 10, as illustrated in FIG. 1, includes at least a liquid crystal panel (display panel) 11 that has a horizontally elongated rectangular shape and is capable of displaying an image, and a backlight device (illumination device) that irradiate the liquid crystal panel 11 with light for use in display. The backlight device includes a light source (for example, an LED or the like) disposed on a rear side (back face side) of the liquid crystal panel 11 and configured to emit light having a white color, an optical member configured to impart an optical effect on the light from the light source, thereby converting the light into planar light, and the like. A center-side portion of a main surface of the liquid crystal panel 11 is a display region AA in which an image is displayed. In contrast, a frame-shaped outer peripheral portion surrounding the display region AA of the main surface of the liquid crystal panel 11 is a non-display region NAA in which no image is displayed.

The liquid crystal panel 11 will be described with reference to FIG. 2 in addition to FIG. 1. As illustrated in FIG. 1 and FIG. 2, the liquid crystal panel 11 is formed by bonding a pair of substrates 20 and 21 together. Of the pair of substrates 20, 21, the substrate on a front side is a counter substrate 20, and the substrate on a rear side is an array substrate 21. The counter substrate 20 and the array substrate 21 are each formed by layering various films on an inner face side of a glass substrate. A liquid crystal layer 22 is interposed between the pair of substrates 20, 21 and contains liquid crystal molecules, which are substances having optical characteristics that change in accordance with application of an electrical field. A sealing portion 23 sealing the liquid crystal layer 22 is interposed between outer peripheral edge portions of the pair of substrates 20 and 21. The sealing portion 23 is formed in a rectangular frame-like shape to surround the liquid crystal layer 22. Note that polarizers 14 are bonded to outer face sides of both the substrates 20, 21, respectively.

As illustrated in FIG. 1 and FIG. 2, the counter substrate 20 has a short side dimension shorter than a short side dimension of the array substrate 21. The counter substrate 20 is bonded to the array substrate 21 with one end portion in a short side direction (Y-axis direction) aligned with the array substrate 21. Accordingly, the other end portion in the short side direction of the array substrate 21 is an exposed portion 21A protruding laterally relative to the counter substrate 20 and becoming exposed. An overall region of this exposed portion 21A is a non-display region NAA, in which a driver 12 for supplying various signals and a flexible substrate 13 are mounted.

The driver 12 includes an LSI chip having a drive circuit therein. The driver 12 is mounted on the exposed portion 21A of the array substrate 21 in a chip-on-glass (COG) manner. The driver 12 processes various signals transmitted by the flexible substrate 13. As illustrated in FIG. 1 and FIG. 2, the driver 12 is adjacent to one side of the display region AA in the Y-axis direction, and is sandwiched between the flexible substrate 13 to be described below and the display region AA. The driver 12 has a horizontally elongated rectangular planar shape. The driver 12 has a long side dimension smaller than a long side dimension of the display region AA. An outer peripheral portion constituting the outer shape of the driver 12 includes a pair of long side portions and a pair of short side portions. Of the pair of long side portions of the driver 12, a long side portion closer to the display region AA is defined as a first side portion 12A closest to the display region AA in the outer peripheral portion. The pair of short side portions of the driver 12 are both continuous with the first side portion 12A, and one (right side in FIG. 1) of the pair of the short side portions is defined as a second side portion 12B. The first side portion 12A is parallel to the X-axis direction (first direction). The second side portion 12B is parallel to the Y-axis direction (second direction). The driver 12 can supply various signals to a source wiring line 27 and the like provided on the array substrate 21.

The flexible substrate 13 has a configuration in which a wiring line pattern including a plurality of wiring lines are formed on a base material made of a synthetic resin material (for example, a polyimide resin or the like) having insulating properties and flexibility. As illustrated in FIG. 1 and FIG. 2, one end side of the flexible substrate 13 is connected to the exposed portion 21A of the array substrate 21, and the other end side thereof is connected to an external circuit substrate (control substrate, or the like). The flexible substrate 13 is connected to an end portion of the exposed portion 21A on a side opposite to the display region AA side in the Y-axis direction with respect to the driver 12. That is, the flexible substrate 13 is attached to the exposed portion 21A at a position where the driver 12 is interposed between the flexible substrate 13 and the display region AA.

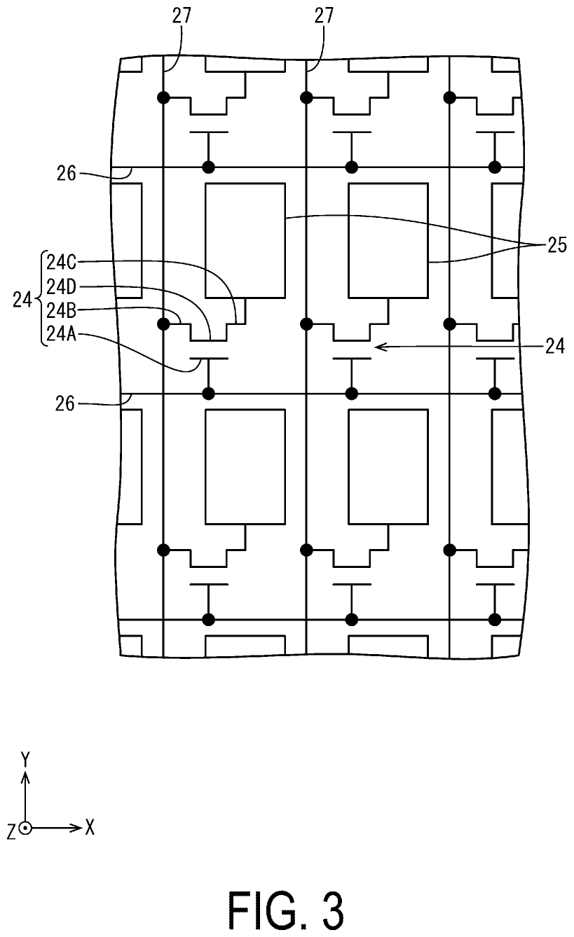

Next, a configuration of the display region AA in the array substrate 21 will be described with reference to FIG. 3. As illustrated in FIG. 3, at least a TFT (thin film transistor, switching element) 24 and a pixel electrode 25 are provided on an inner surface side of the display region AA of the array substrate 21. A plurality of the TFTs 24 and a plurality of the pixel electrodes 25 are provided in a matrix shape with intervals therebetween in the X-axis direction and the Y-axis direction. Gate wiring lines (scanning wiring lines) 26 and source wiring lines (image wiring lines, signal wiring lines) 27 substantially orthogonal to (intersecting) each other are provided around the TFTs 24 and the pixel electrodes 25. The gate wiring lines 26 extend along the X-axis direction and a plurality of the gate wiring lines 26 are arranged at intervals in the Y-axis direction. The source wiring lines 27 extend along the Y-axis direction and a plurality of the source wiring lines 27 are arranged at intervals in the X-axis direction. The TFT 24 includes a gate electrode 24A which is connected to the gate wiring line 26, a source electrode 24B which is connected to the source wiring line 27, a drain electrode 24C which is connected to the pixel electrode 25, and a semiconductor portion 24D which is connected to the source electrode 24B and the drain electrode 24C and includes a semiconductor material. The TFT 24 is driven based on a scanning signal supplied to the gate electrode 24A by the gate wiring line 26. Then, a potential of an image signal (data signal) supplied from the driver 12 to the source electrode 24B through the source wiring line 27 is supplied to the drain electrode 24C through the semiconductor portion 24D. As a result, the pixel electrode 25 is charged to the potential based on the image signal. The pixel electrode 25 is disposed in a region surrounded by the gate wiring line 26 and the source wiring line 27, and has a substantially rectangular planar shape, for example. The pixel electrode 25 overlaps with a color filter disposed in the display region AA of the counter substrate 20, and constitutes a pixel together with the color filter. The color filter exhibits three colors: blue (B), green (G), and red (R). Note that alignment films for aligning the liquid crystal molecules included in the liquid crystal layer 22 are respectively provided on innermost faces of both of the substrates 20, 21.

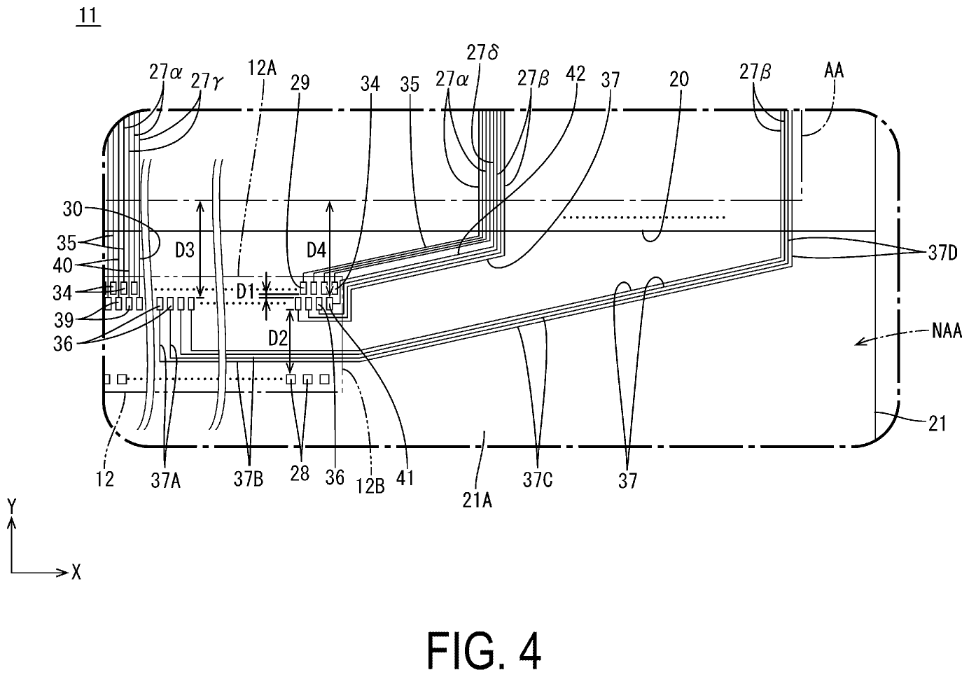

As illustrated in FIG. 4, wiring lines and terminals for supplying various signals (potentials) to the gate wiring lines 26, the source wiring lines 27, and the like are provided on the inner surface side of the exposed portion 21A which is the non-display region NAA of the array substrate 21. A plurality of terminals 28, 29 to be connected to the driver 12 to be mounted on the exposed portion 21A are provided in a placement region (mounting region) of the driver 12 overlapping with the driver 12 in a plan view, of the exposed portion 21A. In addition, a plurality of terminals to be connected to the flexible substrate 13 to be mounted are also provided in a placement region of the flexible substrate 13, of the exposed portion 21A. Note that in FIG. 4, an outer shape of the driver 12 to be mounted on the exposed portion 21A is indicated by a two dots-dashed line.

As illustrated in FIG. 4, the plurality of terminals 28, 29 include a plurality of input terminals 28 for inputting signals to the driver 12 and a plurality of output terminals 29 for receiving an output of signals from the driver 12. Each of the input terminals 28 and the output terminals 29 has a vertically elongated rectangular planar shape, and is disposed in such a manner that long sides thereof are parallel to the Y-axis direction and short sides thereof are parallel to the X-axis direction. The input terminals 28 are larger in size and area in a plan view than the output terminals 29. The number of the output terminals 29 is larger than the number of the input terminals 28. Note that the signals to be output from the driver 12 to the output terminals 29 include at least an image signal. The signals to be output from the driver 12 to the output terminals 29 may include a scanning signal, a common potential signal of a common potential, a ground potential signal of a ground potential, and the like in addition to the image signal.

As illustrated in FIG. 4, the input terminals 28 are located on a side farther from the display region AA (the first side portion 12A of the driver 12) in the Y-axis direction than the output terminals 29. Specifically, the input terminals 28 are disposed at positions close to a side portion farthest from the display region AA, in the outer peripheral portion of the driver 12 in the Y-axis direction. The plurality of input terminals 28 form one row, and are linearly arranged at intervals along the X-axis direction. That is, the plurality of input terminals 28 are aligned in such a manner that both end positions thereof in the Y-axis direction are substantially the same. The output terminals 29 are located closer to the display region AA (the first side portion 12A of the driver 12) in the Y-axis direction than the input terminals 28.

As illustrated in FIG. 4, the plurality of output terminals 29 form two rows spaced apart from each other in the Y-axis direction. A plurality of output terminals 29 forming one row (upper side) are disposed closer to the display region AA (first side portion 12A) in the Y-axis direction than a plurality of output terminals 29 forming the other row (lower side). Specifically, the output terminals 29 forming the one row are disposed at positions close to the first side portion 12A of the driver 12 in the Y-axis direction. The plurality of output terminals 29 forming the one row are linearly arranged at intervals along the X-axis direction. That is, the plurality of output terminals 29 forming the one row are aligned in such a manner that both end positions thereof in the Y-axis direction are substantially the same. The plurality of output terminals 29 forming the other row are linearly arranged at intervals along the X-axis direction, similarly to the one row. That is, the plurality of output terminals 29 forming the other row are aligned in such a manner that both end positions thereof in the Y-axis direction are substantially the same. An arrangement interval of the plurality of output terminals 29 forming the other row is the same as an arrangement interval of the plurality of output terminals 29 forming the one row. An interval between two output terminals 29 adjacent to each other in the X-axis direction is set to a dimension to the extent that allows a source lead-out wiring line 30 described below to pass therethrough. A distance D1 in the Y-axis direction between the plurality of output terminals 29 forming the one row and the plurality of output terminals 29 forming the other row is about the same as the interval between two output terminals 29 adjacent to each other in the X-axis direction. A distance D2 in the Y-axis direction between the plurality of output terminals 29 forming the other row and the plurality of input terminals 28 is greater than the distance D1 in the Y-axis direction between the plurality of output terminals 29 forming the one row and the plurality of output terminals 29 forming the other row. The plurality of output terminals 29 forming the one row and the plurality of output terminals 29 forming the other row are positionally displaced from each other in the X-axis direction. An amount of the positional displacement in the X-axis direction between the plurality of output terminals 29 forming the one row and the plurality of output terminals 29 forming the other row is about half an array pitch of the output terminals 29. As described above, the plurality of output terminals 29 forming the two rows are arranged in a staggered manner as a whole.

As illustrated in FIG. 4, the plurality of output terminals 29 are connected to a plurality of source lead-out wiring lines (lead-out wiring lines for image wiring lines) 30 led out from the plurality of source wiring lines 27 disposed in the display region AA. Note that in FIG. 4, only some of the plurality of source lead-out wiring lines 30 are representatively illustrated. Each of the source lead-out wiring lines 30 is connected to an end portion closer to the driver 12 in the Y-axis direction, of both end portions of each of the source wiring lines 27 extending along the Y-axis direction in the display region AA. In the non-display region NAA, the plurality of source lead-out wiring lines 30 extend from the placement region (the output terminals 29 to be connected) of the driver 12 toward the display region AA. Here, the driver 12 has a long side dimension smaller than the short side dimension of the display region AA (see FIG. 1). Thus, the plurality of source lead-out wiring lines 30 are routed to spread in a fan shape from the driver 12 side toward the display region AA side. A detailed configuration of the source lead-out wiring lines 30 will be described below again.

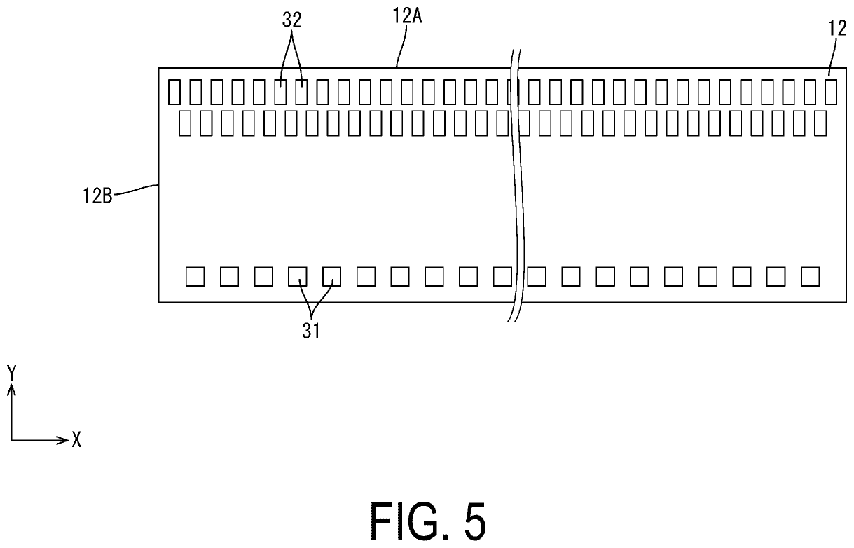

As illustrated in FIG. 5, a plurality of bumps 31, 32 to be connected to the plurality of terminals 28, 29 are provided on a main surface (bottom surface) facing the array substrate 21, of the driver 12. The bumps 31, 32 are provided to protrude in the Z-axis direction from the main surface of the driver 12 toward the array substrate 21 side. The bumps 31, 32 are connected to a circuit provided inside the driver 12. On the bottom surface of the driver 12, a plurality of the bumps 31 are arranged at positions overlapping with the terminals 28 and a plurality of the bumps 32 are arranged at positions overlapping with the terminals 29 on the array substrate 21 side. The plurality of bumps 31, 32 include a plurality of input bumps 31 for receiving an input of signals from the array substrate 21 and a plurality of output bumps 32 for outputting signals to the array substrate 21. Each of the input bumps 31 and the output bumps 32 has a vertically elongated rectangular planar shape, and is disposed in such a manner that long sides thereof are parallel to the Y-axis direction and short sides thereof are parallel to the X-axis direction. The input bumps 31 are larger in size and area in a plan view than the output bumps 32. The number of the output bumps 32 is larger than that of the input bumps 31.

As illustrated in FIG. 5, the input bumps 31 are disposed on a side farther from the first side portion 12A in the Y-axis direction than the output bumps 32, that is, at positions closer to a fourth side portion 12D. The plurality of input bumps 31 form one row, and are linearly arranged at intervals along the X-axis direction. That is, the plurality of input bumps 31 are aligned in such a manner that both end positions thereof in the Y-axis direction are substantially the same. The output bumps 32 are disposed closer to the display region AA in the Y-axis direction than the input bumps 31, that is, at positions closer to the first side portion 12A. When the driver 12 is attached to the array substrate 21, the plurality of input bumps 31 are disposed at positions overlapping with the plurality of input terminals 28 in a plan view, and are connected to the plurality of input terminals 28 overlapping with the plurality of input bumps 31.

As illustrated in FIG. 5, the plurality of output bumps 32 form two rows spaced apart from each other in the Y-axis direction. A plurality of output bumps 32 forming one (upper) row are disposed closer to the first side portion 12A in the Y-axis direction than a plurality of output bumps 32 forming the other (lower) row. The plurality of output bumps 32 forming the one row are linearly arranged at intervals along the X-axis direction. Similarly to the one row, the plurality of output bumps 32 forming the other row are linearly arranged at intervals along the X-axis direction, and an arrangement interval thereof is the same as an arrangement interval of the plurality of output bumps 32 forming the one row. An interval between two output bumps 32 adjacent to each other in the X-axis direction is set to a dimension to the extent that allows a source lead-out wiring line 30 described below to pass therethrough. The plurality of output bumps 32 forming the one row and the plurality of output bumps 32 forming the other row are positionally displaced from each other in the X-axis direction. An amount of the positional displacement in the X-axis direction between the plurality of output bumps 32 forming the one row and the plurality of output bumps 32 forming the other row is about half an array pitch of the output bumps 32. As described above, the plurality of output bumps 32 forming the two rows are arranged in a staggered manner as a whole. When the driver 12 is attached to the array substrate 21, the plurality of output bumps 32 are disposed at positions overlapping with the plurality of output terminals 29 in a plan view, and are connected to the plurality of output terminals 29 overlapping with the plurality of output bumps 32.

As illustrated in FIG. 6, the terminals 28, 29 of the array substrate 21 and the bumps 31, 32 of the driver 12 are connected to each other via an anisotropic conductive film (ACF) 33. Note that in FIG. 6, a connection structure of the output terminals 29 and the output bumps 32 is illustrated as a representative, but a connection structure of the input terminals 28 and the input bumps 31 is the same. The anisotropic conductive film 33 will be described. The anisotropic conductive film 33 is formed by dispersing and blending a large number of conductive particles 33B in a binder 33A including a thermosetting resin material. When mounting the driver 12, the anisotropic conductive film 33 and the driver 12 are set in the placement region of the driver 12 on the array substrate 21, and in this state, the driver 12 is subjected to thermocompression bonding by applying a load toward the array substrate 21. Then, the terminals 28, 29 on the array substrate 21 side and the bumps 31, 32 on the driver 12 side are electrically connected via the conductive particles 33B. In addition, the binder 33A is thermally cured to mechanically fix the driver 12 to the array substrate 21.

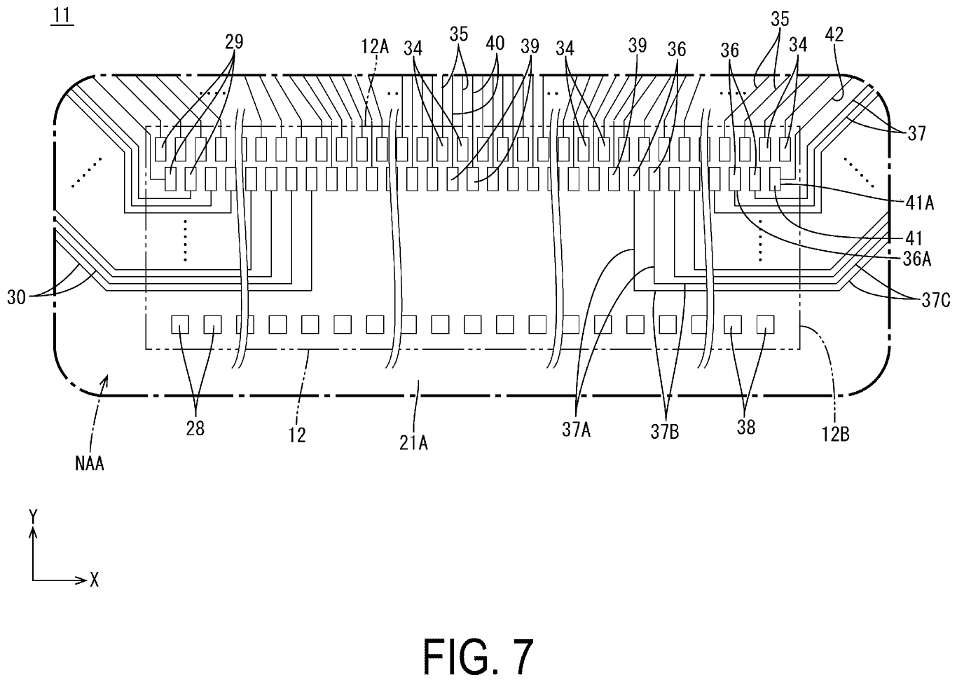

Next, a detailed configuration of the source lead-out wiring line 30 will be described by mainly referring to FIG. 4 and FIG. 7. Note that in FIG. 7, the outer shape of the driver 12 to be mounted on the exposed portion 21A is indicated by a two dots-dashed chain line. First, in the present embodiment, as illustrated in FIG. 4 and FIG. 7, all the plurality of output terminals 29 forming the one (upper) row closer to the display region AA than the other (lower) row are referred to as a plurality of “first terminals 34”. In the present embodiment, among the plurality of source lead-out wiring lines 30, all the plurality of source lead-out wiring lines 30 connected to the plurality of first terminals 34 are referred to as a plurality of “first wiring lines 35”. In the present embodiment, among the plurality of output terminals 29 forming the other row farther from the display region AA than the one row, the plurality of output terminals 29 located on the center side in the X-axis direction are referred to as a plurality of “fourth terminals 39”, the output terminals 29 located at the ends in the X-axis direction are referred to as “fifth terminals 41”, and all the plurality of output terminals 29 sandwiched between the fourth terminals 39 and the fifth terminals 41 are referred to as a plurality of “second terminals 36”. In the present embodiment, among the plurality of source lead-out wiring lines 30, the plurality of source lead-out wiring lines 30 connected to the plurality of second terminals 36 are referred to as a plurality of “second wiring lines 37”, the plurality of source lead-out wiring lines 30 connected to the plurality of fourth terminals 39 are referred to as a plurality of “third wiring lines 40”, and the plurality of source lead-out wiring lines 30 connected to the fifth terminals 41 are referred to as a plurality of “fourth wiring lines 42”. In the present embodiment, all the plurality of input terminals 28 are referred to as a plurality of “third terminals 38”.

As illustrated in FIG. 7, each of the first wiring lines 35 is connected to a side portion closest to the display region AA in an outer peripheral portion of each of the first terminals 34 having a rectangular planar shape, and extends from the side portion toward the display region AA. Each of the plurality of first wiring lines 35 is disposed across the first side portion 12A in the outer peripheral portion of the driver 12. The plurality of first wiring lines 35 are bent in the middle from the first terminals 34 to the source wiring lines 27 and extend along a direction oblique to the X-axis direction and the Y-axis direction. As illustrated in FIG. 4 and FIG. 7, each inclined portion of the plurality of first wiring lines 35 tends to have a larger inclination angle with respect to the Y-axis direction when the first terminals 34 to be connected are closer to the end of the driver 12 in the X-axis direction.

As illustrated in FIG. 7, the second wiring lines 37 are connected to the second terminals 36 which are located farther from the display region AA than the first terminals 34 and are interposed between the fourth terminals 39 and the fifth terminals 41 in the X-axis direction. Each of the second wiring lines 37 is connected to a third side portion 36A which is a side portion farthest from the display region AA in an outer peripheral portion of each of the second terminals 36 having a rectangular planar shape, and is routed from the third side portion 36A to the display region AA. As illustrated in FIG. 4 and FIG. 7, each of the plurality of second wiring lines 37 is disposed across the second side portion 12B in the outer peripheral portion of the driver 12. That is, in the present embodiment, the first wiring lines 35 extending from the first terminals 34 are disposed across the first side portion 12A of the driver 12, whereas the second wiring lines 37 connected to the second terminals 36 located farther from the display region AA than the first terminals 34 are disposed across the second side portion 12B of the driver 12. According to this configuration, as compared with a case where both the first wiring lines 35 and the second wiring lines 37 are disposed across the first side portion 12A of the driver 12, a region in which the first wiring lines 35 and the second wiring lines 37 are routed is widely secured. Specifically, the first wiring lines 35 crossing the first side portion 12A are routed by using a region existing between the first side portion 12A and the display region AA in the Y-axis direction until reaching the display region AA, whereas the second wiring lines 37 crossing the second side portion 12B are routed by using a region existing on a lateral side (right side in FIG. 4 and FIG. 7) of the second side portion 12B in the X-axis direction until reaching the display region AA. With this configuration, even when the frame is made smaller, a problem is less likely to occur in routing the first wiring lines 35 and the second wiring lines 37.

As illustrated in FIG. 4, the distance D2 between the second terminals 36 to be connected to the second wiring lines 37 and the third terminals 38 is larger than the distance D1 between the first terminals 34 and the second terminals 36. That is, there is a larger region between the second terminals 36 and the third terminals 38 than between the first terminals 34 and the second terminals 36. In order to use the large region between the second terminals 36 and the third terminals 38, the second wiring lines 37 are disposed so as to extend from the third side portion 36A in the outer peripheral portion of the second terminals 36, which is closest to the third terminals 38, toward the third terminals 38 (the side opposite to the display region AA), and then cross the second side portion 12B. This configuration is more suitable in making the frame smaller.

Specifically, as illustrated in FIG. 4, the second wiring lines 37 extend from the second terminals 36 toward the third terminals 38 and are then bent three times in the middle to be connected to the source wiring lines 27 provided in the display region AA. Each of the second wiring lines 37 includes a first wiring line component 37A, a second wiring line component 37B, a third wiring line component 37C, and a fourth wiring line component 37D described below. The first wiring line component 37A is a portion of the second wiring line 37, which extends from the third side portion 36A of each of the second terminals 36 toward each of the third terminals 38 along the Y-axis direction. The second wiring line component 37B is a portion of the second wiring line 37, which is bent at an extending end position of the first wiring line component 37A, extends toward the second side portion 12B along the X-axis direction, and crosses the second side portion 12B. The third wiring line component 37C is a portion of the second wiring line 37, which is bent at an extending end position of the second wiring line component 37B and extends toward the display region AA along an oblique direction with respect to the X-axis direction and the Y-axis direction. The fourth wiring line component 37D is a portion of the second wiring line 37, which is bent at an extending end position of the third wiring line component 37C, extends toward the display region AA along the Y-axis direction, and is connected to each of the source wiring lines 27.

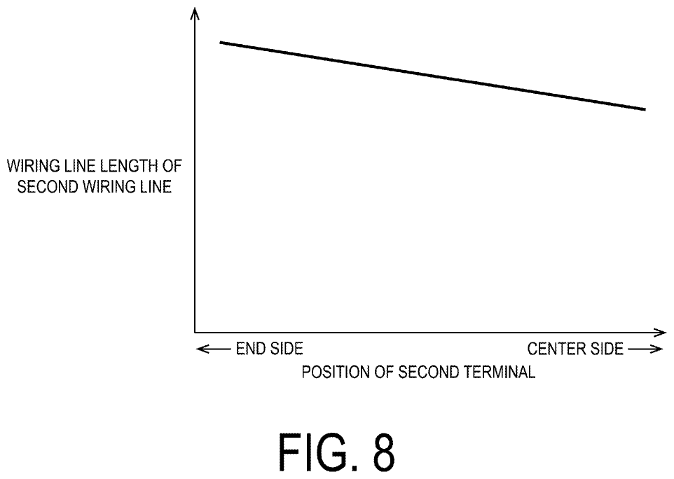

As illustrated in FIG. 4 and FIG. 7, the plurality of second wiring lines 37 are configured in such a manner that lengths of the first wiring line components 37A that are portions extending from the second terminals 36 toward the third terminals 38 become shorter as the second terminals 36 to be connected come closer to the second side portion 12B. For more detail, among the plurality of second wiring lines 37, the second wiring line 37 connected to the second terminal 36 closest to the fourth terminals 39 (located closest to the center of the driver 12 in the X-axis direction) is connected to the source wiring line 27 located closest to the end of the display region AA in the X-axis direction and having the longest first wiring line component 37A. Among the plurality of second wiring lines 37, the second wiring line 37 connected to the second terminal 36 closest to the fifth terminal 41 (located closest to the end of the driver 12 in the X-axis direction) is connected to a source wiring line 27 adjacent to the source wiring line 27 connected to the fourth wiring lines 42 described below in the display region AA and having the shortest first wiring line component 37A. As described above, the plurality of second wiring lines 37 have a configuration that the lengths of the first wiring line components 37A and the entire wiring line lengths of the second wiring lines 37 continuously vary depending on the positions of the second terminals 36 to be connected in the placement region of the driver 12 in the X-axis direction. Now, FIG. 8 is a graph showing a relationship between a position in the X-axis direction of the second terminal 36 to be connected in the placement region of the driver 12 and the entire wiring line length of the second wiring line 37. In FIG. 8, the horizontal axis represents the position of the second terminal 36 in the X-axis direction in the placement region of the driver 12, and the vertical axis represents the entire wiring line length of the second wiring line 37. The right side in the horizontal axis in FIG. 8 coincides with the center side of the placement region of the driver 12 in the X-axis direction, and the left side in the horizontal axis coincides with the end side of the placement region of the driver 12 in the X-axis direction. According to FIG. 8, the entire wiring line length of the second wiring line 37 tends to become continuously and gradually shorter with the position of the second terminal 36 from the end side toward the center side in the X-axis direction in the placement region of the driver 12, and conversely becomes continuously and gradually longer with the position of the second terminal 36 from the center side toward the end side. Accordingly, a display defect caused by dullness that may occur in image signals transmitted by the plurality of second wiring lines 37 is less likely to be visually recognized.

As illustrated in FIG. 7, the third wiring lines 40 are connected to the fourth terminals 39 located closer to the center side in the X-axis direction in the placement region of the driver 12 than the second terminals 36. The fourth terminals 39 to be connected to the third wiring lines 40 are located farther from the second side portion 12B of the driver 12 than any of the second terminals 36, and a distance to the fourth terminals 39 from the display region AA is equal to the distance D3 from the display region AA to the second terminals 36 (see FIG. 4). Similarly to the first wiring lines 35, the third wiring lines 40 are bent in the middle from the fourth terminals 39 to the source wiring lines 27 and extend along an oblique direction with respect to the X-axis direction and the Y-axis direction. Each of the third wiring lines 40 is connected to a side portion closest to the display region AA in an outer peripheral portion of each of the fourth terminals 39 having a rectangular planar shape, extends from the side portion of the fourth terminal 39 toward the display region AA, and is disposed across the first side portion 12A. As described above, similarly to the first wiring lines 35, the third wiring lines 40 are routed by using a region between the first side portion 12A and the display region AA in the Y-axis direction until reaching the display region AA, and thus, the region between the second terminals 36 and the third terminals 38 can be exclusively used for routing the second wiring lines 37. This configuration is further suitable in making the frame smaller.

As illustrated in FIG. 7, the plurality of second terminals 36 and the plurality of fourth terminals 39 are disposed at positions displaced in the X-axis direction with respect to the plurality of first terminals 34. That is, the plurality of first terminals 34, the plurality of second terminals 36, and the plurality of fourth terminals 39 are arranged in a staggered manner in a plan view. Each of the third wiring lines 40 extending from the fourth terminals 39 toward the display region AA passes between two first terminals 34 adjacent to each other in the X-axis direction and then is disposed across the first side portion 12A. The third wiring lines 40 are parallel to the first wiring lines 35 and each pass between two first wiring lines 35 adjacent to each other in the X-axis direction. The plurality of first wiring lines 35 and the plurality of third wiring lines 40 are alternately arranged at intervals in the X-axis direction. In this manner, the plurality of third wiring lines 40 can be routed not to be short-circuited to the first terminals 34 or the first wiring lines 35. In addition, the third wiring lines 40 are not routed in the region between the second terminals 36 and the third terminals 38, and thus, the region between the second terminals 36 and the third terminals 38 can be exclusively used for routing the plurality of second wiring lines 37. This configuration is still more suitable in making the frame smaller.

As illustrated in FIG. 4, the fourth wiring line 42 is connected to the fifth terminal 41 closer to the end side in the placement region of the driver 12 than the second terminals 36 in the X-axis direction. The fifth terminal 41 to be connected to the fourth wiring line 42 is located closer to the second side portion 12B of the driver 12 than any of the second terminals 36, and a distance D4 to the fifth terminal 41 from the display region AA is equal to the distance D3 from the display region AA to the second terminals 36. The fifth terminal 41 is located closest to the end in the X-axis direction among the plurality of output terminals 29 forming the other (lower) row. The fourth wiring line 42 is connected to a fourth side portion 41A which is a side portion closest to the second side portion 12B in an outer peripheral portion of the fifth terminal 41 having a rectangular planar shape, extends from the fourth side portion 41A toward the display region AA, and is disposed across the second side portion 12B. As described above, the fourth wiring line 42 is routed to cross the second side portion 12B from the fourth side portion 41A of the fifth terminal 41, which is closest to the second side portion 12B, and is not routed in the region between the second terminals 36 and the third terminals 38. As a result, the region between the second terminals 36 and the third terminals 38 can be exclusively used for routing the second wiring lines 37, which is more suitable in making the frame smaller.

In the present embodiment, as illustrated in FIG. 4, all the output terminals 29 are connected to the source wiring lines 27 via the source lead-out wiring lines 30. The plurality of source wiring lines 27 arranged at intervals in the X-axis direction in the display region AA include a plurality of first source wiring lines (first image wiring lines) 27a to be connected to the plurality of first wiring lines 35, a plurality of second source wiring lines (second image wiring lines) 270 to be connected to the plurality of second wiring lines 37, a plurality of third source wiring lines (third image wiring lines) 27y to be connected to the plurality of third wiring lines 40, and a fourth source wiring line (fourth image wiring line) 276 to be connected to the fourth wiring line 42. The plurality of first source wiring lines 27a are disposed in a center-side portion of the display region AA excluding both end-side portions thereof in the X-axis direction. The plurality of second source wiring lines 270 are disposed in both end-side portions of the display region AA in the X-axis direction, and are located closer to the end of the display region AA in the X-axis direction than any of the first source wiring lines 27a. The third source wiring lines 27y are repeatedly arranged alternately with the first source wiring lines 27a in the center-side portion of the display region AA in the X-axis direction. The fourth source wiring line 276 is interposed between the first source wiring lines 27a and the second source wiring line 270 in the center-side portion of the display region AA in the X-axis direction. In the present embodiment, the plurality of second wiring lines 37 to be connected to the plurality of second source wiring lines 270 disposed at both end-side portions of the display region AA in the X-axis direction are disposed across the second side portion 12B of the driver 12. As a result, the region in which the plurality of first wiring lines 35 and the plurality of second wiring lines 37 are routed is sufficiently widely secured, which is more suitable to achieve a higher definition and a smaller frame.

As described above, the liquid crystal display device (display device) 10 of the present embodiment includes: the liquid crystal panel (display panel) 11 having the main surface including the display region AA in which an image is displayed and the non-display region NAA surrounding the display region AA; the driver 12 attached to the non-display region NAA of the liquid crystal panel 11; the first terminals 34 provided at positions overlapping with the driver 12 in the non-display region NAA of the liquid crystal panel 11; the first wiring lines 35 provided in the non-display region NAA of the liquid crystal panel 11 and connected to the first terminals 34; the second terminals 36 provided at positions in the non-display region NAA of the liquid crystal panel 11, the positions overlapping with the driver 12 and being farther from the display region AA than the first terminals 34; and the second wiring lines 37 provided in the non-display region NAA of the liquid crystal panel 11 and connected to the second terminals 36, in which the driver 12 has a rectangular planar shape, has a side portion closest to the display region AA and in an outer peripheral portion as the first side portion 12A, and has one side portion of two side portions connected to the first side portion 12A as the second side portion 12B, the first wiring lines 35 extend from the first terminals 34 and are disposed across the first side portion 12A, and the second wiring lines 37 extend from the second terminals 36 and are disposed across the second side portion 12B.

When the driver 12 is attached to the non-display region NAA of the liquid crystal panel 11, the driver 12 is connected to the first terminals 34 and the second terminals 36 of the liquid crystal panel 11. Signals output from the driver 12 are supplied to the first wiring lines 35 and the second wiring lines 37 via the first terminals 34 and the second terminals 36. The first wiring lines 35 connected to the first terminals 34 extend from the first terminals 34 and are disposed across the first side portion 12A of the driver 12, whereas the second wiring lines 37 connected to the second terminals 36 extend from the second terminals 36 and are disposed across the second side portion 12B of the driver 12. According to this configuration, as compared with a case where both the first wiring lines 35 and the second wiring lines 37 are disposed across the first side portion 12A of the driver 12, a region in which the first wiring lines 35 and the second wiring lines 37 are routed is widely secured. With this configuration, even when the frame is made smaller, a problem is less likely to occur in routing the first wiring lines 35 and the second wiring lines 37.

In addition, the liquid crystal display device 10 includes the third terminals 38 provided at positions in the non-display region NAA of the liquid crystal panel 11, the positions overlapping with the driver 12 and being farther from the display region AA than the second terminals 36, the third terminals 38 are disposed at positions in which the distance D2 between the third terminals 38 and the second terminals 36 is larger than the distance D1 between the first terminals 34 and the second terminals 36, and the second wiring lines 37 extend from the second terminals 36 toward the third terminals 38 and cross the second side portion 12B. There is a larger region between the second terminals 36 and the third terminals 38 than between the first terminals 34 and the second terminals 36. The second wiring lines 37 are routed by using the region between the second terminals 36 and the third terminals 38, which is more suitable in making the frame smaller.

The plurality of second terminals 36 are arranged at intervals in the first direction being a direction parallel to the first side portion 12A, the plurality of second wiring lines 37 are provided to be connected to the plurality of second terminals 36, respectively, and the plurality of second wiring lines 37 have extension lengths extending from the second terminals 36 toward the third terminals 38, the extension lengths becoming shorter as the second terminals 36 to be connected come closer to the second side portion 12B. With this configuration, it is possible to continuously change wiring line lengths and wiring line resistances of the plurality of second wiring lines 37. Accordingly, a display defect caused by dullness that may occur in signals transmitted by the plurality of second wiring lines 37 is less likely to be visually recognized.

Furthermore, the liquid crystal display device 10 includes the fourth terminals 39 provided at positions in the non-display region NAA of the liquid crystal panel 11, the positions overlapping with the driver 12 and being farther from the second side portion 12B than the second terminals 36, and the third wiring lines 40 provided in the non-display region NAA of the liquid crystal panel 11 and connected to the fourth terminals 39, the distance from the display region AA to the fourth terminals 39 is equal to the distance D3 from the display region AA to the second terminals 36, and the third wiring lines 40 extend from the fourth terminals 39 and are disposed across the first side portion 12A. The third wiring lines 40 connected to the fourth terminals 39 extend from the fourth terminals 39 and are disposed across the first side portion 12A of the driver 12, and thus, the region between the second terminals 36 and the third terminals 38 can be exclusively used for routing the second wiring lines 37. This configuration is further suitable in making the frame smaller.

In addition, a plurality of the first terminals 34, a plurality of the second terminals 36, and a plurality of the fourth terminals 39 are arranged at intervals in the first direction being a direction parallel to the first side portion 12A, a plurality of the first wiring lines 35, a plurality of the second wiring lines 37, and a plurality of the third wiring lines 40 are provided to be connected to the plurality of the first terminals 34, the plurality of the second terminals 36, and the plurality of the fourth terminals 39, respectively, the plurality of the second terminals 36 and the plurality of the fourth terminals 39 are disposed at positions displaced in the first direction with respect to the plurality of the first terminals 34, and each of the plurality of the third wiring lines 40 passes between two of the plurality of the first terminals 34 adjacent to each other in the first direction. With this configuration, each of the third wiring lines 40 connected to the fourth terminals 39 extends from the fourth terminal 39, passes between two first terminals 34 adjacent to each other in the first direction, and crosses the first side portion 12A of the driver 12. This makes it easy to route the plurality of third wiring lines 40. Furthermore, the region between the second terminals 36 and the third terminals 38 can be exclusively used for routing the plurality of second wiring lines 37, which is more suitable in making the frame smaller.

In addition, each of the second terminals 36 has a rectangular planar shape, and has a side portion farthest from the display region AA and in an outer peripheral portion as the third side portion 36A, and each of the second wiring lines 37 is connected to the third side portion 36A of each of the second terminals 36. As compared with a case where each of the second wiring lines 37 is connected to a side portion other than the third side portion 36A in the outer peripheral portion of each of the second terminals 36, the second wiring lines 37 can be easily extended from the second terminals 36 toward the third terminals 38.

In addition, the liquid crystal display device 10 includes: the fifth terminal 41 provided at a position in the non-display region NAA of the liquid crystal panel 11, the position overlapping with the driver 12 and being closer to the second side portion 12B than the second terminals 36; and the fourth wiring line 42 provided in the non-display region NAA of the liquid crystal panel 11 and connected to the fifth terminal 41, in which the distance D4 from the display region AA to the fifth terminal 41 is equal to the distance D3 from the display region AA to the second terminals 36, the fifth terminal 41 has a rectangular planar shape, and has a side portion closest to the second side portion 12B and in an outer peripheral portion as the fourth side portion 41A, and the fourth wiring line 42 is connected to the fourth side portion 41A of the fifth terminal 41 and is disposed across the second side portion 12B. The fifth terminal 41 is provided at the position closer to the second side portion 12B of the driver 12 than the second terminals 36, the position where the distance D4 from the display region AA to the fifth terminal 41 is equal to the distance D3 from the display region AA to the second terminals 36. The fourth wiring line 42 connected to the fifth terminal 41 is connected to the fourth side portion 41A of the fifth terminal 41 and is disposed across the second side portion 12B of the driver 12, and thus, the region between the second terminals 36 and the third terminals 38 can be exclusively used for routing the second wiring lines 37. This configuration is further suitable in making the frame smaller.

In addition, the liquid crystal display device 10 includes: the plurality of pixel electrodes 25 provided in the display region AA of the liquid crystal panel 11; the plurality of TFTs (switching elements) 24 provided in the display region AA of the liquid crystal panel 11 and connected to the plurality of pixel electrodes 25; and the plurality of source wiring lines (image wiring lines) 27 provided in the display region AA of the liquid crystal panel 11 and connected to the plurality of TFTs 24, and the plurality of source wiring lines 27 include: the first source wiring lines (first image wiring line) 27a arranged at intervals in the first direction that is a direction parallel to the first side portion 12A and connected to the first wiring lines 35; and the second source wiring lines (second image wiring lines) 270 connected to the second wiring lines 37 and located closer to the end of the display region AA in the first direction than the first source wiring lines 27a. With this configuration, signals transmitted by the first wiring lines 35 are supplied to the first source wiring lines 27a, and signals transmitted by the second wiring lines 37 are supplied to the second source wiring lines 270. Incidentally, when the number of the pixel electrodes 25, the TFTs 24, and the source wiring lines 27 increases as the liquid crystal panel 11 progresses to a higher definition, the number of the first wiring lines 35 and the second wiring lines 37 also tends to increase. On the other hand, the second wiring lines 37 are disposed across the second side portion 12B of the driver 12 to sufficiently widely secure the region in which the first wiring lines 35 and the second wiring lines 37 are routed, which is more suitable for achieving a higher definition and a smaller frame.

### Second Embodiment

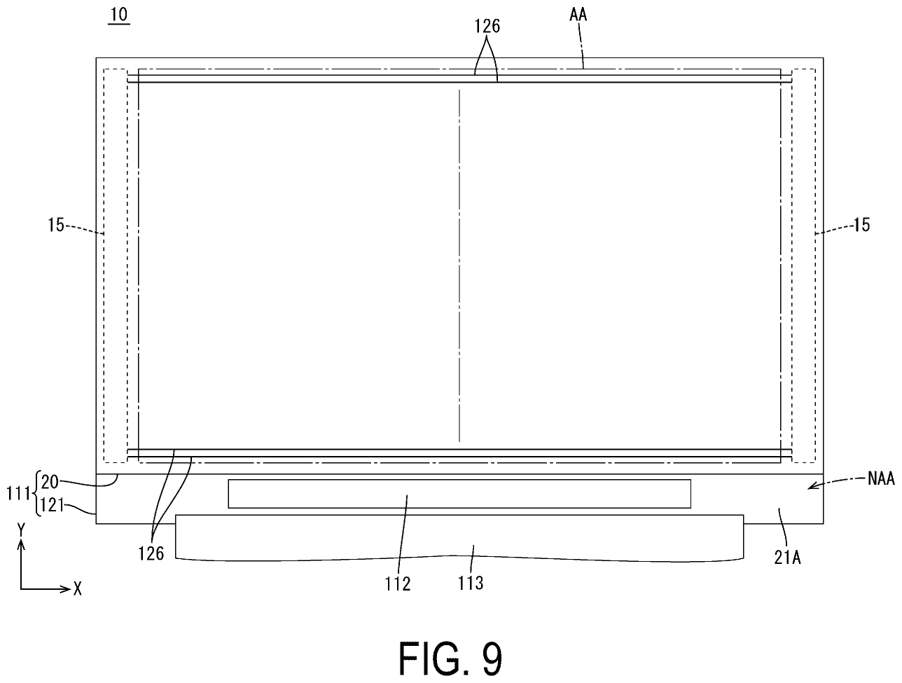

A second embodiment will be described with reference to FIGS. 9 to 11. In this second embodiment, a case where a configuration of a liquid crystal panel 111 is changed will be described. Further, repetitive descriptions of structures, actions, and effects similar to those of the first embodiment described above will be omitted.

In the liquid crystal panel 111 according to the present embodiment, as illustrated in FIG. 9, a gate circuit portion (scanning circuit portion) 15 is provided at a position aligned with the display region AA in the X-axis direction. In a non-display region NAA of an array substrate 121 forming the liquid crystal panel 111, a pair of the gate circuit portions 15 is provided, sandwiching the display region AA therebetween from both sides in the X-axis direction. The gate circuit portions 15 are each monolithically provided on the array substrate 121, and are connected to end portions of a plurality of gate wiring lines 126 disposed in the display region AA. The gate circuit portions 15 are each a so-called shift register circuit, process a signal transmitted to the array substrate 121 by a flexible substrate 113, and supply a scanning signal to the plurality of gate wiring lines 126 sequentially from an upper stage side. The gate circuit portions 15 extend along the Y-axis direction which is the arrangement direction of the gate wiring lines 126.

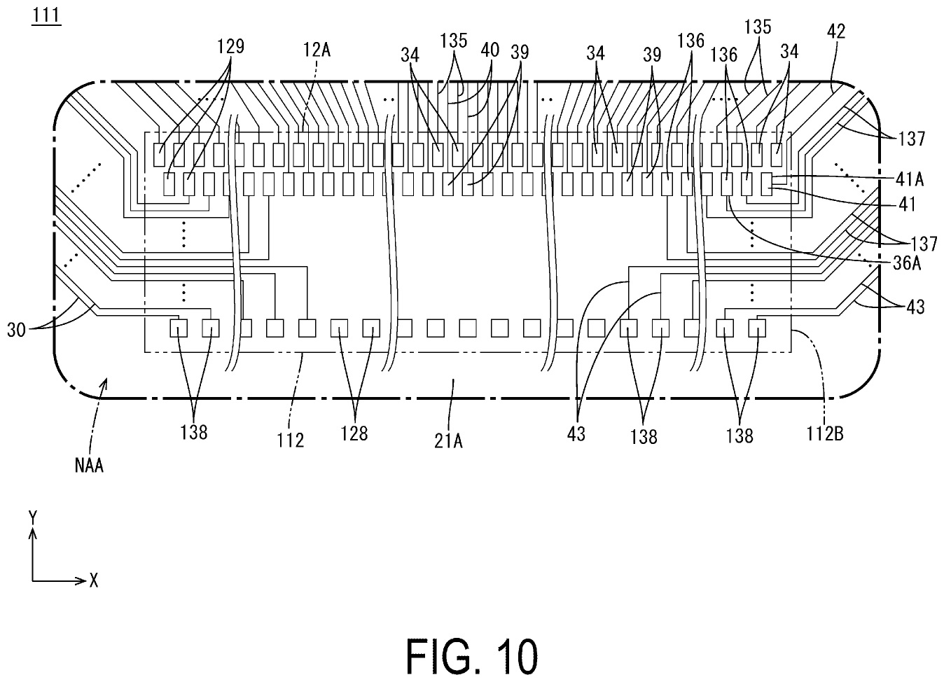

In the present embodiment, as illustrated in FIG. 10, some of a plurality of output terminals 129 are disposed in the same row as input terminals 128 in the placement region of a driver 112. Hereinafter, the output terminals 129 disposed in the same row as the input terminals 128 are referred to as “third terminals 138”. Each of the third terminals 138 has substantially the same planar shape and size as those of each of the input terminals 128. A distance from the display region AA to the third terminals 138 in the Y-axis direction is the same as a distance from the display region AA to the input terminals 128. A plurality of third terminals 138 are arranged at intervals in the X-axis direction in both end-side portions in the placement region of the driver 112 in the X-axis direction. The plurality of input terminals 128 are sandwiched from both sides by the plurality of third terminals 138. Control signals such as a clock signal and a start pulse signal for operating a shift register circuit of each of the gate circuit portions 15 and a power supply voltage are supplied from the driver 112 or the like to the plurality of third terminals 138.

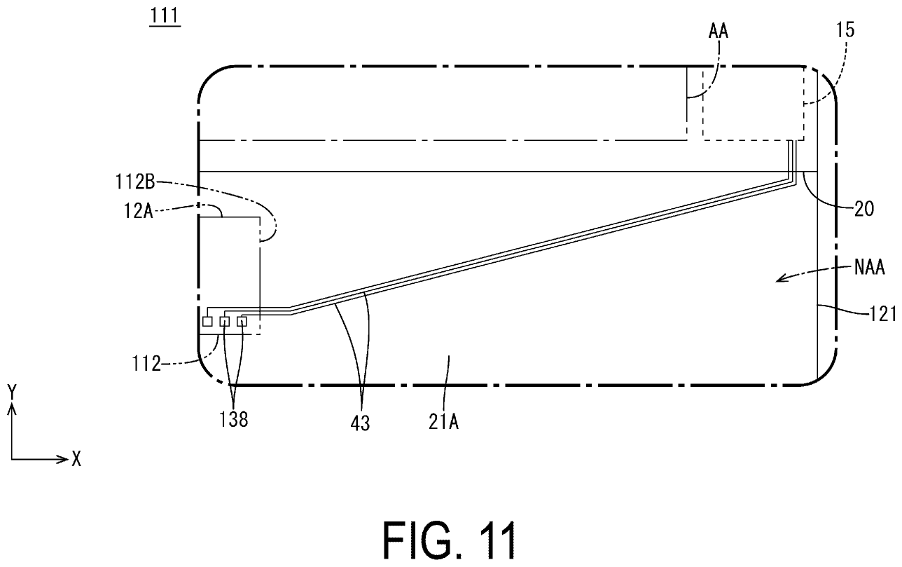

In the non-display region NAA of the array substrate 121, as illustrated in FIG. 10 and FIG. 11, fifth wiring lines 43 connected to the third terminals 138 and the gate circuit portions 15 is provided. Note that in FIG. 11, configurations of terminals and wiring lines other than the third terminals 138 and the fifth wiring lines 43 are not illustrated. The control signals and the power supply voltage supplied to the third terminals 138 are supplied to the gate circuit portions 15 through the fifth wiring lines 43. Each of the fifth wiring lines 43 is connected to a side portion closest to the display region AA in an outer peripheral portion of each of the third terminals 138 having a rectangular planar shape, and is routed from the side portion to the gate circuit portions 15. Specifically, the fifth wiring lines 43 extend from the third terminals 138 toward the second terminals 136 and are then bent three times in the middle to be connected to the gate circuit portions 15. Each of the fifth wiring lines 43 has portions parallel to wiring line components 137A, 137B, 137C of each of the second wiring lines 137, respectively, and the portion parallel to the second wiring line component 137B crosses a second side portion 112B of the driver 112. In the present embodiment, a region between the second terminals 136 and the third terminals 138 is exclusively used for routing the plurality of second wiring lines 137 and the plurality of fifth wiring lines 43. That is, in the present embodiment, although the region between the second terminals 136 and the third terminals 138 cannot be exclusively used for routing the plurality of second wiring lines 137, the second wiring lines 137 are disposed across the second side portion 112B of the driver 112 to sufficiently widely secure the region for routing the first wiring lines 135 and the second wiring lines 137, and thus, the region for routing the fifth wiring lines 43 can be sufficiently secured. This configuration is more suitable in making the frame smaller.

As described above, according to the present embodiment, the display device includes: the third terminals 138 provided at positions in the non-display region NAA of the liquid crystal panel 111, the positions overlapping with the driver 112 and being farther from the display region AA than the second terminals 136; the fifth wiring lines 43 in the non-display region NAA of the liquid crystal panel 111 and connected to the third terminals 138; the gate wiring lines (scanning wiring lines) 126 provided in the display region AA of the liquid crystal panel 111 and connected to the TFTs 24 (see FIG. 3); and the gate circuit portions (scanning circuit portions) 15 provided in the non-display region NAA of the liquid crystal panel 111 and connected to the gate wiring lines 126, in which the fifth wiring lines 43 extend from the third terminals 138, are disposed across the second side portion 112B, and are connected to the gate circuit portions 15. With this configuration, signals transmitted by the fifth wiring lines 43 are supplied to the gate circuit portions 15 connected to the gate wiring lines 126. In the non-display region NAA of the liquid crystal panel 111, it is necessary to secure a region in which the fifth wiring lines 43 are routed from the third terminals 138 to the gate circuit portions 15. On the other hand, the second wiring lines 137 are disposed across the second side portion 112B of the driver 112 to sufficiently widely secure the region in which the first wiring lines 135 and the second wiring lines 137 are routed, and thus, the region in which the fifth wiring lines 43 are routed can be sufficiently secured. This configuration is more suitable in making the frame smaller.

### Third Embodiment

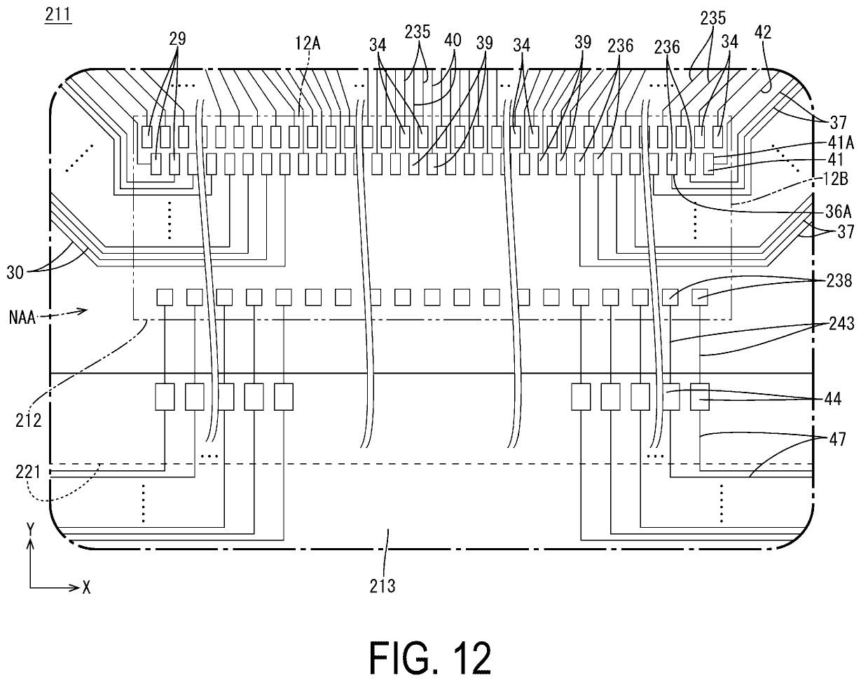

A third embodiment will be described with reference to FIGS. 12 to 14. In the third embodiment, a case where configurations of a liquid crystal panel 211 and a flexible substrate 213 are changed from the second embodiment described above will be described. Further, repetitive descriptions of structures, actions, and effects similar to those of the second embodiment described above will be omitted.

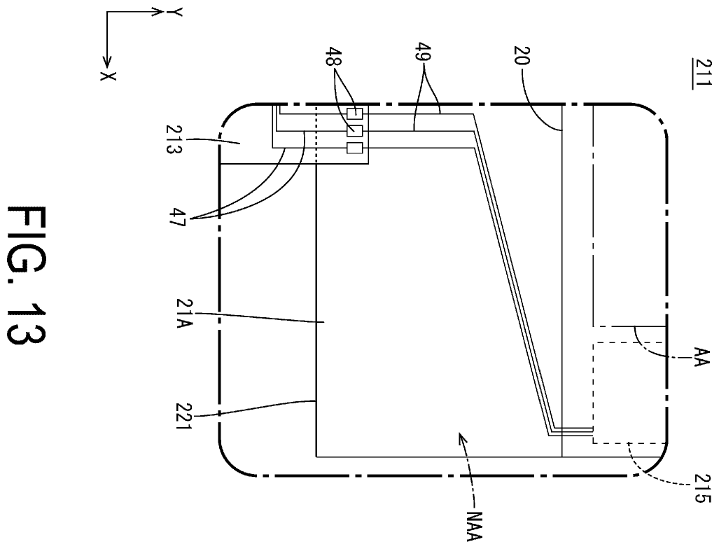

As illustrated in FIG. 12 and FIG. 13, the liquid crystal panel 211 and the flexible substrate 213 according to the present embodiment are provided with terminals 44, 45, 46, 48 and wiring lines 47, 49 for supplying a control signal or a power supply voltage to be supplied to third terminals 238 to a gate circuit portion 215. An array substrate 221 forming the liquid crystal panel 211 is provided with sixth terminals 44, ninth terminals 48, and seventh wiring lines 49. The flexible substrate 213 is provided with seventh terminals 45, eighth terminals 46, and sixth wiring lines 47.

As illustrated in FIG. 12 and FIG. 13, a plurality of sixth terminals 44 and a plurality of ninth terminals 48 are provided in a placement region of the flexible substrate 213, which is a region overlapping with the flexible substrate 213 in a plan view, in the non-display region NAA of the array substrate 221. As illustrated in FIG. 12, the plurality of sixth terminals 44 are disposed in a center-side portion in the X-axis direction in the placement region of the flexible substrate 213, and are arranged at intervals in the Y-axis direction with respect to the plurality of third terminals 238 provided in a placement region of a driver 212. The plurality of sixth terminals 44 are arranged at intervals in the X-axis direction. Although an arrangement interval of the plurality of sixth terminals 44 in the X-axis direction is generally larger than an arrangement interval of the plurality of third terminals 238 in the X-axis direction, a specific magnitude relationship can be arbitrarily set. Fifth wiring lines 243 are appropriately routed from the third terminals 238 to the sixth terminals 44. The fifth wiring lines 243 are disposed across a side portion farthest from the display region AA, in an outer peripheral portion of the driver 212. Note that the plurality of fifth wiring lines 243 may include a wiring line crossing the second side portion 12B of the driver 212. As illustrated in FIG. 13, the plurality of ninth terminals 48 are disposed at end-side portions in the X-axis direction in the placement region of the flexible substrate 213. That is, the plurality of ninth terminals 48 are provided at positions closer to the ends in the X-axis direction than the plurality of sixth terminals 44. In the non-display region NAA of the array substrate 221, the seventh wiring lines 49 are routed from the ninth terminals 48 to the gate circuit portion 215 and are connected to the ninth terminals 48 and the gate circuit portion 215.

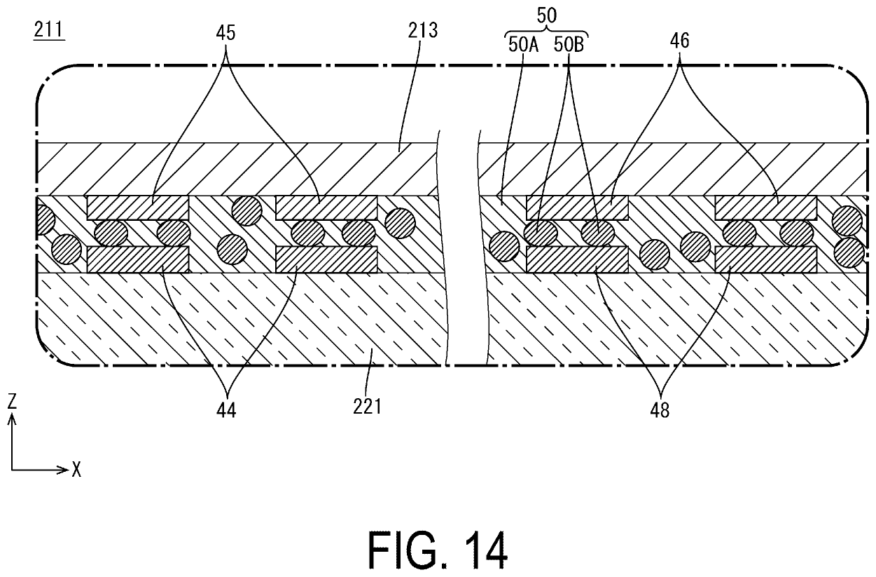

As illustrated in FIG. 14, a plurality of seventh terminals 45 and a plurality of eighth terminals 46 are provided in a portion of the flexible substrate 213 overlapping with the array substrate 221 in a plan view. The plurality of seventh terminals 45 are arranged at positions overlapping with the plurality of sixth terminals 44 in a plan view. The plurality of seventh terminals 45 are arranged at intervals in the X-axis direction in a center-side portion of the flexible substrate 213 in the X-axis direction, and an array pitch thereof is substantially equal to an array pitch of the plurality of sixth terminals 44 (see FIG. 12). The plurality of eighth terminals 46 are arranged at positions overlapping with the plurality of ninth terminals 48 in a plan view. The plurality of eighth terminals 46 are arranged at intervals in the X-axis direction in end-side portions of the flexible substrate 213 in the X-axis direction, and an array pitch thereof is substantially equal to an array pitch of the plurality of ninth terminals 48 (see FIG. 13). An anisotropic conductive film 50 is provided between the flexible substrate 213 and the array substrate 221 in the same manner as between the driver 212 and the array substrate 221. The sixth terminals 44 and the seventh terminals 45 overlapping with each other, and the eighth terminals 46 and the ninth terminals 48 overlapping with each other are connected to each other via the anisotropic conductive film 50, respectively. The anisotropic conductive film 50 is formed by dispersing and blending a large number of conductive particles 50B in a binder 50A including a thermosetting resin material. When the flexible substrate 213 is mounted, the anisotropic conductive film 50 and the flexible substrate 213 are set in the placement region of the flexible substrate 213 in the array substrate 221, and in this state, the flexible substrate 213 is thermocompression-bonded by applying a load toward the array substrate 221. Then, the terminals 44, 48 on the array substrate 221 side and the terminals 45, 46 on the flexible substrate 213 side are electrically connected via the conductive particles 50B. In addition, when the binder 50A is thermally cured, the flexible substrate 213 is mechanically fixed to the array substrate 221. As illustrated in FIGS. 12 and 13, the sixth wiring lines 47 are provided to extend from the seventh terminals 45 toward the eighth terminals 46 on the flexible substrate 213, and are connected to the seventh terminals 45 and the eighth terminals 46.

According to such a configuration, as illustrated in FIGS. 12 to 14, a control signal or a power supply voltage supplied to the third terminal 238 is transmitted to the seventh terminals 45 of the flexible substrate 213 via the fifth wiring lines 243 and the sixth terminals 44, and is transmitted to the ninth terminals 48 of the liquid crystal panel 211 via the sixth wiring lines 47 and the eighth terminals 46. The control signal or the power supply voltage transmitted to the ninth terminals 48 is supplied to the gate circuit portion 215 by the seventh wiring lines 49. As described above, the fifth wiring lines 243 and the gate circuit portion 215 are connected to each other via the configuration (the seventh terminals 45, the sixth wiring lines 47, and the eighth terminals 46) included in the flexible substrate 213, and thus, as compared with a case where the fifth wiring lines are directly connected to the gate circuit portion 215, it is possible to secure a wider region in which first wiring lines 235 and the second wiring lines 237 are routed in the non-display region NAA of the liquid crystal panel 211. This configuration is more suitable in making the frame smaller.

As described above, according to the present embodiment, the liquid crystal display device includes: the flexible substrate 213 attached to the non-display region NAA of the liquid crystal panel 211 at a position where the driver 212 is sandwiched between the flexible substrate 213 and the display region AA; the third terminals 238 provided at positions in the non-display region NAA of the liquid crystal panel 211, the positions overlapping with the driver 212 and being farther from the display region AA than the second terminals 236; the fifth wiring lines 243 provided in the non-display region NAA of the liquid crystal panel 211 and connected to the third terminals 238; the gate wiring lines 226 provided in the display region AA of the liquid crystal panel 211 and connected to the TFTs 24 (see FIG. 3); the gate circuit portion 215 provided at a position in the non-display region NAA of the liquid crystal panel 211 and connected to the gate wiring lines 226, the position being aligned with the display region AA in the first direction; the sixth terminals 44 provided at positions in the non-display region NAA of the liquid crystal panel 211 and connected to the fifth wiring lines 243, the positions overlapping with the flexible substrate 213; the seventh terminals 45 provided at positions in the flexible substrate 213 and connected to the sixth terminals 44, the positions overlapping with the liquid crystal panel 211; the eighth terminals 46 provided at positions in the flexible substrate 213, the positions overlapping with the liquid crystal panel 211 and being closer to an end in the first direction than the seventh terminals 45; the sixth wiring lines 47 provided in the flexible substrate 213 and connected to the seventh terminals 45 and the eighth terminals 46; the ninth terminals 48 provided at positions in the non-display region NAA of the liquid crystal panel 211 and connected to the eighth terminals 46, the positions overlapping with the flexible substrate 213 and being closer to an end in the first direction than the sixth terminal 44; and the seventh wiring lines 49 provided in the non-display region NAA of the liquid crystal panel 211 and connected to the ninth terminals 48 and the gate circuit portion 215. Signals transmitted by the fifth wiring lines 243 are transmitted to the seventh terminals 45 of the flexible substrate 213 via the sixth terminals 44, and are transmitted to the ninth terminals 48 of the liquid crystal panel 211 via the sixth wiring lines 47 and the eighth terminals 46. The signals transmitted to the ninth terminals 48 are supplied to the gate circuit portion 215 by the seventh wiring lines 49. As described above, the fifth wiring lines 243 and the gate circuit portion 215 are connected to each other via the configuration (the seventh terminals 45, the sixth wiring lines 47, and the eighth terminals 46) included in the flexible substrate 213, and thus, as compared with a case where the fifth wiring lines are directly connected to the gate circuit portion 215, it is possible to secure a wider region in which first wiring lines 235 and the second wiring lines 237 are routed in the non-display region NAA of the liquid crystal panel 211. This configuration is more suitable in making the frame smaller.

### Fourth Embodiment

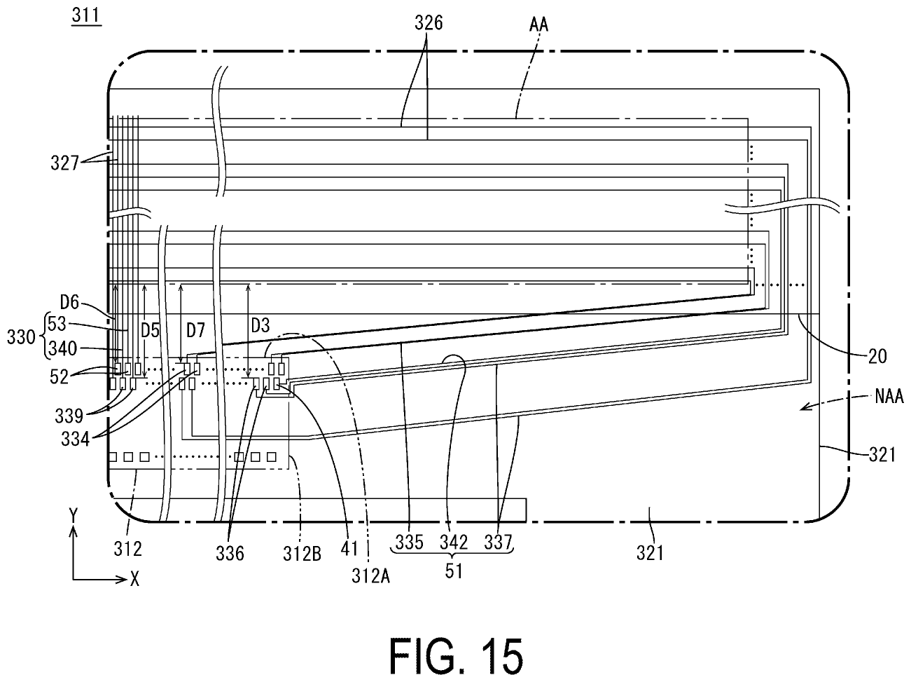

A fourth embodiment will be described with reference to FIG. 15. In the fourth embodiment, a case where the configuration of a liquid crystal panel 311 is changed from the configuration of the first embodiment described above will be described. Further, repetitive descriptions of structures, actions, and effects similar to those of the first embodiment described above will be omitted.

In the liquid crystal panel 311 according to the present embodiment, as illustrated in FIG. 15, a plurality of output terminals 329 are connected to source lead-out wiring lines 330 and a plurality of gate lead-out wiring lines (lead-out wiring lines for scanning wiring lines) 51 led out from a plurality of gate wiring lines 326 disposed in the display region AA. In the non-display region NAA of the array substrate 321, the plurality of gate lead-out wiring lines 51 are routed from end portions of the gate wiring lines 326 to a placement region of a driver 312. In the present embodiment, a plurality of source lead-out wiring lines 330 are connected to a plurality of output terminals 329 (fourth terminals 339 and tenth terminals 52 to be described below) located on the center side in the X-axis direction in the placement region of the driver 312, among the plurality of output terminals 329. On the other hand, the plurality of gate lead-out wiring lines 51 are connected to a plurality of output terminals 329 (first terminals 334, second terminals 336, and fifth terminals 341) located on the center side in the X-axis direction in the placement region of the driver 312, among the plurality of output terminals 329.

In the present embodiment, among the plurality of output terminals 329, among a plurality of output terminals 329 forming one row close to the display region AA, a plurality of output terminals 329 located on an end side in the X-axis direction are referred to as a plurality of “first terminals 334”, and a plurality of output terminals 329 located on the center side in the X-axis direction are referred to as a plurality of “tenth terminals 52”. In the present embodiment, among the plurality of source lead-out wiring lines 330, a plurality of source lead-out wiring lines 330 connected to the plurality of tenth terminals 52 are referred to as a plurality of “eighth wiring lines 53”. In the present embodiment, among the plurality of gate lead-out wiring lines 51, a plurality of gate lead-out wiring lines 51 connected to the plurality of first terminals 334 are referred to as a plurality of “first wiring lines 335”, a plurality of gate lead-out wiring lines 51 connected to the plurality of second terminals 336 are referred to as a plurality of “second wiring lines 337”, and a plurality of gate lead-out wiring lines 51 connected to the fifth terminals 341 are referred to as “fourth wiring lines 342”.

The plurality of tenth terminals 52 are provided at positions farther from a second side portion 312B than any of the first terminals 334 in the placement region of the driver 312. In the center-side portion of the placement region of the driver 312, the plurality of fourth terminals 339 and the plurality of tenth terminals 52 are planarly arranged in a staggered manner. A distance D5 to the fourth terminals 339 from the display region AA is equal to a distance D3 from the display region AA to the second terminals 336. On the other hand, a distance D6 to the tenth terminals 52 from the display region AA is equal to a distance D7 from the display region AA to the first terminals 334. Each of third wiring lines 340 extending from the fourth terminals 339 toward the display region AA passes between two tenth terminals 52 adjacent to each other in the X-axis direction and is then disposed across a first side portion 312A. Each of the eighth wiring lines 53 is connected to a side portion closest to the display region AA in an outer peripheral portion of each of the tenth terminals 52 having a rectangular planar shape, extends from the side portion of the tenth terminal 52 toward the display region AA, and is disposed across the first side portion 312A.

The third wiring lines 340 and the eighth wiring lines 53, which are the source lead-out wiring lines 330, are connected to end portions of a plurality of source wiring lines 327, respectively. On the other hand, the first wiring lines 335, the second wiring lines 337, and the fourth wiring lines 342, which are the gate lead-out wiring lines 51, are connected to end portions of the plurality of gate wiring lines 326, respectively. In such a configuration, an image signal is supplied from the driver 312 to each of the fourth terminals 339 and the tenth terminals 52, whereas a scanning signal is supplied from the driver 312 to each of the first terminals 334, the second terminals 336, and the fifth terminal 341. The image signals supplied to the fourth terminals 339 and the tenth terminals 52 are transmitted through the third wiring lines 340 and the eighth wiring lines 53 to be supplied to the plurality of source wiring lines 327. The scanning signals supplied to the first terminals 334, the second terminals 336, and the fifth terminal 341 are transmitted through the first wiring lines 335, the second wiring lines 337, and the fourth wiring line 342 to be supplied to the plurality of gate wiring lines 326. In the present embodiment, the plurality of second wiring lines 337 connected to the plurality of gate wiring lines 326 are disposed across the second side portion 312B of the driver 312. With this configuration, a region in which the plurality of first wiring lines 335 and the plurality of second wiring lines 337 are routed is sufficiently widely secured, which is more suitable for achieving a higher definition and a smaller frame.

As described above, according to the present embodiment, the liquid crystal display device includes: the plurality of pixel electrodes 25 (see FIG. 3) provided in the display region AA of the liquid crystal panel 311; the plurality of TFTs 24 (see FIG. 3) provided in the display region AA of the liquid crystal panel 311 and connected to the plurality of pixel electrodes 25; the plurality of source wiring lines 327 provided in the display region AA of the liquid crystal panel 311 and connected to the plurality of TFTs 24; the plurality of gate wiring lines 326 provided in the display region AA of the liquid crystal panel 311 and connected to the plurality of TFTs 24; the fourth terminals 339 provided at positions in the non-display region NAA of the liquid crystal panel 311, the positions overlapping with the driver 312 and being farther from the second side portion 312B than the second terminals 336; the third wiring lines 340 provided in the non-display region NAA of the liquid crystal panel 311 and connected to the fourth terminals 339; the tenth terminals 52 provided at positions in the non-display region NAA of the liquid crystal panel 311, the positions overlapping with the driver 312 and being farther from the second side portion 312B than the first terminal 334; and the eighth wiring lines 53 provided in the non-display region NAA of the liquid crystal panel 311 and connected to the tenth terminals 52, in which the distance D5 to the fourth terminals 339 from the display region AA is equal to the distance D3 from the display region AA to the second terminals 336, the third wiring lines 340 extend from the fourth terminals 339 and are disposed across the first side portion 312A, the distance D6 to the tenth terminals 52 from the display region AA is equal to the distance D7 from the display region AA to the first terminals 334, the eighth wiring lines 53 extend from the tenth terminals 52 and disposed across the first side portion 312A, the third wiring lines 340 and the eighth wiring lines 53 are connected to the plurality of source wiring lines 327, respectively, and the first wiring lines 335 and the second wiring lines 337 are connected to the plurality of gate wiring lines 326, respectively. With this configuration, signals transmitted through the third wiring lines 340 and the eighth wiring lines 53 are supplied to the plurality of source wiring lines 327, respectively, and signals transmitted through the first wiring lines 335 and the second wiring lines 337 are supplied to the plurality of gate wiring lines 326, respectively. Incidentally, when the number of the pixel electrodes 25, the TFTs 24, the source wiring lines 327, and the gate wiring lines 326 increases as the liquid crystal panel 311 progresses to a higher definition, the number of the first wiring lines 335, the second wiring lines 337, the third wiring lines 340, and the eighth wiring lines 53 also tends to increase. On the other hand, the second wiring lines 337 are disposed across the second side portion 312B of the driver 312 to sufficiently widely secure a region in which the first wiring lines 335 and the second wiring lines 337 are routed. This is more suitable for achieving a higher definition and a smaller frame.

### Other Embodiments

The techniques disclosed herein are not limited to the embodiments described above and illustrated in the drawings, and the following embodiments, for example, are also included within the technical scope.

(1) The second terminals 36, 136, 336 and the second wiring lines 37, 137, 337 may be provided instead of the fifth terminals and the fourth wiring lines.

(2) In the configuration described in the second embodiment, the gate circuit portions 15 may be omitted, and the fifth wiring lines 43 may be connected to the gate wiring lines 126.

(3) In the configuration described in the third embodiment, the gate circuit portions 215 may be omitted, and the seventh wiring lines 49 may be connected to the gate wiring lines 226.

(4) In the configuration described in the fourth embodiment, the gate circuit portions 15, 215 may be provided, and the first wiring lines 335, the second wiring lines 337, and the fourth wiring lines 342 may be connected to the gate circuit portions 15, 215.

(5) The specific routing paths of the first wiring lines 35, 135, 235, 335, the second wiring lines 37, 137, 337, the third wiring lines 40, 340, the fourth wiring lines 42, the fifth wiring lines 43, 243, the sixth wiring lines 47, the seventh wiring lines 49, and the eighth wiring lines 53 can be changed as appropriate from those illustrated in the drawings.

(6) The plurality of output terminals 29, 129, 329 may be arranged to form three or more rows at intervals in the Y-axis direction.

(7) The plurality of output terminals 29, 129, 329 forming one row and the plurality of output terminals 29, 129, 329 forming the other row may be arranged not to be positionally displaced in the X-axis direction, that is, may be arranged in a matrix shape in a plan view.

(8) In the configurations described in the second and third embodiments, one gate circuit portion 15, 215 may be provided and may be disposed adjacent to one side of the display region AA in the X-axis direction.

(9) The planar shapes of the liquid crystal panels 11, 111, 211, 311 may be vertically long rectangular, square, circular, semi-circular, elliptical, oval, trapezoidal, or the like.

(10) The liquid crystal panels 11, 111, 211, 311 may be a reflective type or a semi-transmissive type, in addition to a transmissive type.

(11) A display panel (an organic EL display panel or the like) other than the liquid crystal panel 11, 111, 211, 311 may be employed.

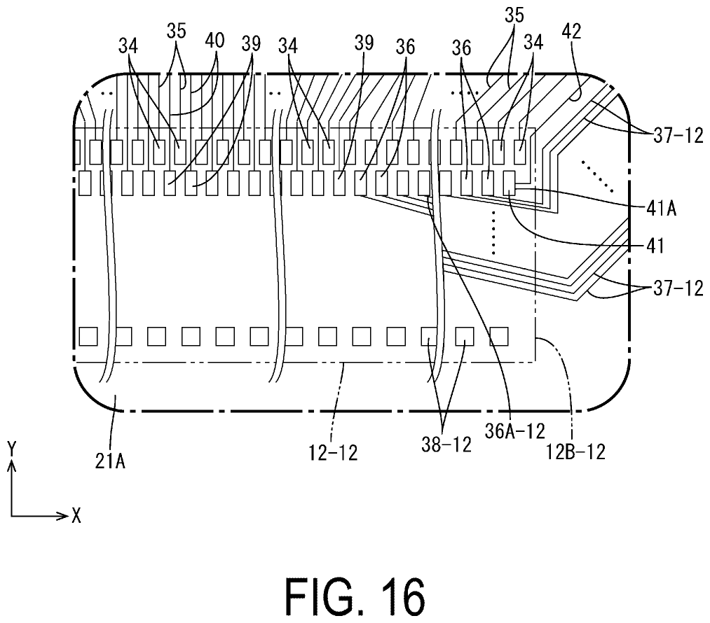

(12) The configuration of second wiring lines 37-12 may be modified as illustrated in FIG. 16. In the second wiring lines 37-12 illustrated in FIG. 16, portions extending from third side portions 36A-12 of second terminals 36-12 toward third terminals 38-12 extend along a direction inclined with respect to the Y-axis direction, and cross a second side portion 12B-12 of a driver 12-12. Even with such a configuration, actions and effects similar to those in the above-described embodiments can be obtained.

(13) The signals output from the drivers 12, 12-12, 112, 212, 312 to the second terminals 36, 36-12, 136, 236, 336 and the fourth terminals 39, 339 may be interchanged.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display panel having a main surface including a display region in which an image is displayed and a non-display region surrounding the display region;
a driver attached to the non-display region of the display panel;
a first terminal provided at a position overlapping with the driver in the non-display region of the display panel;
a first wiring line provided in the non-display region of the display panel and connected to the first terminal;
a second terminal provided at a position in the non-display region of the display panel, the position overlapping with the driver and being farther from the display region than the first terminal; and
a second wiring line provided in the non-display region of the display panel and connected to the second terminal,
wherein the driver has a rectangular planar shape, has a side portion closest to the display region and in an outer peripheral portion as a first side portion, and has one side portion of two side portions connected to the first side portion as a second side portion,
the first wiring line extends from the first terminal and is disposed across the first side portion, and
the second wiring line extends from the second terminal and is disposed across the second side portion.

2. The display device according to claim 1, further comprising
a third terminal provided at a position in the non-display region of the display panel, the position overlapping with the driver and being farther from the display region than the second terminal,
wherein the third terminal is disposed at a position in which a distance between the third terminal and the second terminal is larger than a distance between the first terminal and the second terminal, and
the second wiring line extends from the second terminal toward the third terminal and crosses the second side portion.

3. The display device according to claim 2,
wherein a plurality of the second terminals are arranged at intervals in a first direction being a direction parallel to the first side portion,
a plurality of the second wiring lines are provided to be connected to the plurality of the second terminals, respectively, and
the plurality of the second wiring lines have extension lengths extending from the second terminals toward the third terminal, the extension lengths becoming shorter as the second terminals to be connected come closer to the second side portion.

4. The display device according to claim 2, further comprising:
a fourth terminal provided at a position in the non-display region of the display panel, the position overlapping with the driver and being farther from the second side portion than the second terminal; and
a third wiring line provided in the non-display region of the display panel and connected to the fourth terminal, wherein
a distance to the fourth terminal from the display region is equal to a distance from the display region to the second terminal, and
the third wiring line extends from the fourth terminal and is disposed across the first side portion.

5. The display device according to claim 4,
wherein a plurality of the first terminals, a plurality of the second terminals, and a plurality of the fourth terminals are arranged at intervals in a first direction being a direction parallel to the first side portion,
a plurality of the first wiring lines, a plurality of the second wiring lines, and a plurality of the third wiring lines are provided to be connected to the plurality of the first terminals, the plurality of the second terminals, and the plurality of the fourth terminals, respectively,
the plurality of the second terminals and the plurality of the fourth terminals are disposed at positions displaced in the first direction with respect to the plurality of the first terminals, and
each of the plurality of the third wiring lines passes between two of the plurality of the first terminals adjacent to each other in the first direction.

6. The display device according to claim 4,
wherein the driver is capable of interchanging a signal output to the second terminal and a signal output to the fourth terminal.

7. The display device according to claim 2,
wherein the second terminal has a rectangular planar shape, and has a side portion farthest from the display region and in an outer peripheral portion as a third side portion, and
the second wiring line is connected to the third side portion of the second terminal.

8. The display device according to claim 2, further comprising:
a fifth terminal provided at a position in the non-display region of the display panel, the position overlapping with the driver and being closer to the second side portion than the second terminal; and
a fourth wiring line provided in the non-display region of the display panel and connected to the fifth terminal,
wherein a distance to the fifth terminal from the display region is equal to a distance from the display region to the second terminal, and the fifth terminal has a rectangular planar shape, and has a side portion closest to the second side portion and in an outer peripheral portion as a fourth side portion, and
the fourth wiring line is connected to the fourth side portion of the fifth terminal and is disposed across the second side portion.

9. The display device according to claim 1, further comprising:
a plurality of pixel electrodes provided in the display region of the display panel;
a plurality of switching elements provided in the display region of the display panel and connected to the plurality of pixel electrodes; and
a plurality of image wiring lines provided in the display region of the display panel and connected to the plurality of switching elements,
wherein the plurality of image wiring lines include first image wiring lines arranged at intervals in a first direction being a direction parallel to the first side portion, and connected to the first wiring lines, and second image wiring lines connected to the second wiring lines and located closer to an end of the display region than the first image wiring lines in the first direction.

10. The display device according to claim 9, further comprising:
a third terminal provided at a position in the non-display region of the display panel, the position overlapping with the driver and being farther from the display region than the second terminal;
a fifth wiring line provided in the non-display region of the display panel and connected to the third terminal;
a scanning wiring line provided in the display region of the display panel and connected to the switching element; and
a scanning circuit portion provided in the non-display region of the display panel and connected to the scanning wiring line,
wherein the fifth wiring line extends from the third terminal, is disposed across the second side portion, and is connected to the scanning circuit portion.

11. The display device according to claim 9, further comprising:
a flexible substrate attached to the non-display region of the display panel at a position where the driver is sandwiched between the flexible substrate and the display region;
a third terminal provided at a position in the non-display region of the display panel, the position overlapping with the driver and being farther from the display region than the second terminal;
a fifth wiring line provided in the non-display region of the display panel and connected to the third terminal;
a scanning wiring line provided in the display region of the display panel and connected to the switching element;
a scanning circuit portion provided at a position in the non-display region of the display panel and connected to the scanning wiring line, the position being aligned with the display region in the first direction;
a sixth terminal provided at a position in the non-display region of the display panel and connected to the fifth wiring line, the position overlapping with the flexible substrate;
a seventh terminal provided at a position on the flexible substrate and connected to the sixth terminal, the position overlapping with the display panel;
an eighth terminal provided at a position on the flexible substrate, the position overlapping the display panel and being closer to an end in the first direction than the seventh terminal;
a sixth wiring line provided on the flexible substrate and connected to the seventh terminal and the eighth terminal;
a ninth terminal provided at a position in the non-display region of the display panel and connected to the eighth terminal, the position overlapping with the flexible substrate and being closer to an end in the first direction than the sixth terminal; and
a seventh wiring line provided in the non-display region of the display panel and connected to the ninth terminal and the scanning circuit portion.

12. The display device according to claim 1, further comprising:
a plurality of pixel electrodes provided in the display region of the display panel;
a plurality of switching elements provided in the display region of the display panel and connected to the plurality of pixel electrodes;
a plurality of image wiring lines provided in the display region of the display panel and connected to the plurality of switching elements;
a plurality of scanning wiring lines provided in the display region of the display panel and connected to the plurality of switching elements;
a fourth terminal provided at a position in the non-display region of the display panel, the position overlapping with the driver and being farther from the second side portion than the second terminal;
a third wiring line provided in the non-display region of the display panel and connected to the fourth terminal;
a tenth terminal provided at a position in the non-display region of the display panel, the position overlapping with the driver and being farther from the second side portion than the first terminal; and
an eighth wiring line provided in the non-display region of the display panel and connected to the tenth terminal,
wherein a distance to the fourth terminal from the display region is equal to a distance from the display region to the second terminal,
the third wiring line extends from the fourth terminal and is disposed across the first side portion,
a distance to the tenth terminal from the display region is equal to a distance from the display region to the first terminal,
the eighth wiring line extends from the tenth terminal and is disposed across the first side portion,
the third wiring line and the eighth wiring line are connected to the plurality of image wiring lines, respectively, and
the first wiring line and the second wiring line are connected to the plurality of scanning wiring lines, respectively.
